(19) United States
(12) Patent Application Publication
(10) Pub. No.: US 2024/0268178 A1
(43) Pub. Date: Aug. 8, 2024

(54) Display Device and Display Panel

(71) Applicant: LG Display Co., Ltd., Seoul (KR)

(72) Inventors: Sungwoo Jun, Paju-si (KR); Hyunguk Jang, Seoul (KR); JiAh Kim, Seoul (KR)

(21) Appl. No.: 18/456,292

(22) Filed: Aug. 25, 2023

(30) Foreign Application Priority Data
Jan. 26, 2023 (KR) 10-2023-0009824

(51) Int. Cl. H10K 59/38; H10K 59/122; H10K 59/40; H10K 59/65; H10K 59/80

(52) U.S. Cl. CPC H10K 59/38; H10K 59/122; H10K 59/40; H10K 59/65; H10K 59/873; H10K 59/8792

(57) ABSTRACT

A display device and a display panel are disclosed that includes: a substrate including a display area including an optical area configured to display an image and allow light to be transmitted through the optical area and a normal area located outside of the optical area and configured to display the image; a first light emitting element in the optical area; a first color filter in the optical area and overlapping the light emitting element; and a first light shield in the optical area and overlapping the first light emitting element.

### CROSS-REFERENCE TO RELATED APPLICATION

This application claims the priority benefit of Republic of Korea Patent Application No. 10-2023-0009824, filed on Jan. 26, 2023 in the Korean Intellectual Property Office, which is incorporated by reference in its entirety.

### BACKGROUND

### Technical Field

The present disclosure relates to electronic devices, and more particularly, to a display device and a display panel including one or more optical electronic devices not exposed on front surfaces thereof.

### Description of the Related Art

As display technology advances, display devices can provide increased functions, such as an image capture function, a sensing function, and the like, as well as an image display function. To provide these functions, a display device may need to include one or more optical electronic devices, such as a camera, a sensor for detecting an image, and the like.

In order to receive light transmitting through a front surface of a display device, it may be desirable for such an optical electronic device to be located in an area of the display device where incident light coming from the front surface can be increasingly received and detected. To achieve the foregoing, in a typical display device, an optical electronic device has been designed to be located in a front portion of the display device to allow a camera, a sensor, and/or the like as the optical electronic device to be increasingly exposed to incident light. In order to install an optical electronic device in a display device in this manner, a bezel area of the display device may be increased, or a notch or a hole may be needed to be formed in a display area of an associated display panel.

Therefore, as a display device needs an optical electronic device to receive or detect incident light, and perform an intended function, a size of the bezel in the front portion of the display device may be increased, or a substantial disadvantage may be encountered in designing the front portion of the display device.

In addition, in examples where an optical electronic device is configured in a display device, the quality of images may be unexpectedly decreased and the performance of the optical electronic device may be impaired according to structures in which the optical electronic device is configured in the display device. For example, when the optical electronic device is a camera, image quality acquired by the camera may be decreased.

### SUMMARY

To address these issues, one or more embodiments of the present disclosure may provide a display panel and a display device that include a light transmission structure for enabling one or more optical electronic devices to normally receive light (e.g., visible light, infrared light, ultraviolet light, or the like) while not being exposed in a front surface of the display device.

One or more embodiments of the present disclosure may provide a display panel and a display device that have a structure for enabling expansion of an open area (or increase of an aperture ratio) in an optical area of the display panel overlapping one or more optical electronic devices.

One or more embodiments of the present disclosure may provide a display panel and a display device that have a structure capable of increasing of transmittance (or transmissivity) of an optical area of the display panel overlapping one or more optical electronic devices.

One or more embodiments of the present disclosure may provide a display panel and a display device that have a structure capable of preventing one or more optical electronic devices overlapping an optical area of the display panel from malfunctioning due to external light.

In one embodiment, a display device comprises: a substrate comprising a display area including an optical area configured to display an image and allow light to be transmitted through the optical area and a normal area located outside of the optical area and configured to display the image; a first light emitting element in the optical area; a first color filter in the optical area and overlapping the first light emitting element; and a first light shield in the optical area and overlapping the first light emitting element.

In one embodiment, a display device comprises: a first light emitting element in a first area of a display area of the display panel in which an image is displayed; a first color filter in the first area and overlapping the first light emitting element; a second light emitting element in a second area of the display area that is different from the first area; a second color filter in the second area and overlapping the second light emitting element; a light shield located under the first light emitting element but is non-overlapping with the second light emitting element; and a black matrix on at least one side of the second color filter in the second area without being on the first color filter in the first area.

In one embodiment, a display device comprises: a substrate including a first area configured to display an image and allow external light to be transmitted through the first area, and a second area located outside of the first area and configured to display the image without allowing the external light to be transmitted through the second area; a first light emitting element in the first area, the first light emitting element configured to emit light; a first pixel circuit connected to the first light emitting element, the first pixel circuit in one of the first area or the second area; a first color filter in the first area, the first color filter overlapping the first light emitting element; and a first light shield in the first area, the first light shield layer overlapping the first color filter and the first light emitting element such that an end of the first light shield extends past an end of the first color filter.

According to embodiments of the present disclosure, a display panel and a display device may be provided that include a light transmission structure for enabling one or more optical electronic devices to normally receive light (e.g., visible light, infrared light, ultraviolet light, or the like) while not being exposed in a front surface of the display device.

According to one or more embodiments of the present disclosure, a display panel and a display device may be provided that have a structure for enabling expansion of an open area in an optical area of the display panel overlapping one or more optical electronic devices.

According to one or more embodiments of the present disclosure, a display panel and a display device may be provided that have a structure capable of improving luminance efficiency in an optical area included in a display area of the display panel, and thereby, enabling low-power designs.

According to one or more embodiments of the present disclosure, a display panel and a display device may be provided that have a structure capable of increasing of transmittance (or transmissivity) of an optical area of the display panel overlapping one or more optical electronic devices.

One or more embodiments of the present disclosure can provide an advantage of improving operating performance of one or more optical electronic devices located under the display panel.

According to one or more embodiments of the present disclosure, a display panel and a display device may be provided that have a structure capable of preventing one or more optical electronic devices overlapping an optical area of the display panel from malfunctioning due to external light.

Additional features and aspects will be set forth in part in the description which follows and in part will become apparent from the description or may be learned by practice of the inventive concepts provided herein. Other features and aspects of the inventive concepts may be realized and attained by the structure particularly pointed out in, or derivable from, the written description, the claims hereof, and the appended drawings. Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims. It is to be understood that both the foregoing general description and the following detailed description of the present disclosure are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIGS. 1A, 1B, and 1C illustrate an example display device according to embodiments of the present disclosure;

FIG. 2 illustrates an example system configuration of the display device according to embodiments of the present disclosure;

FIG. 3 illustrates an example display panel according to embodiments of the present disclosure;

FIG. 4 schematically illustrates an example first type of optical area and an example normal area around the first type of optical area in the display panel according to embodiments of the present disclosure;

FIGS. 5 and 6 illustrate example light emitting elements and example pixel circuits for driving the light emitting elements, which are disposed in a normal area, an optical bezel area, and an optical area in the display panel according to embodiments of the present disclosure;

FIG. 7 is an example plan view of the normal area, the optical bezel area, and the optical area included in the display panel according to embodiments of the present disclosure;

FIGS. 8 and 9 are example cross-sectional views of the display panel and cross-sectional views of the optical bezel area and the optical area of the display panel according to embodiments of the present disclosure;

FIG. 10 illustrates an example second type of optical area and an example normal area around the second type of optical area included in the display panel according to embodiments of the present disclosure;

FIG. 11 is an example plan view of the second type of optical area in the display panel according to embodiments of the present disclosure;

FIG. 12 is an example cross-sectional view of the second type of optical area in the display panel according to embodiments of the present disclosure;

FIG. 13 is a plan view illustrating an example structure capable of improving display performance in the optical area of the display panel according to embodiments of the present disclosure;

FIG. 14 is an example cross-sectional view taken along line A-A′ of FIG. 13 according to embodiments of the present disclosure.

FIG. 15 is a plan view illustrating an example structure capable of expanding an open area and increasing transmittance in the optical area of the display panel according to embodiments of the present disclosure;

FIG. 16 is an example cross-sectional view taken along line B-B′ of FIG. 15 according to embodiments of the present disclosure; and

FIG. 17 is an example cross-sectional view of the normal area in the display panel according to embodiments of the present disclosure.

### DETAILED DESCRIPTION

Reference will now be made in detail to embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various embodiments of the present disclosure will be described in detail.

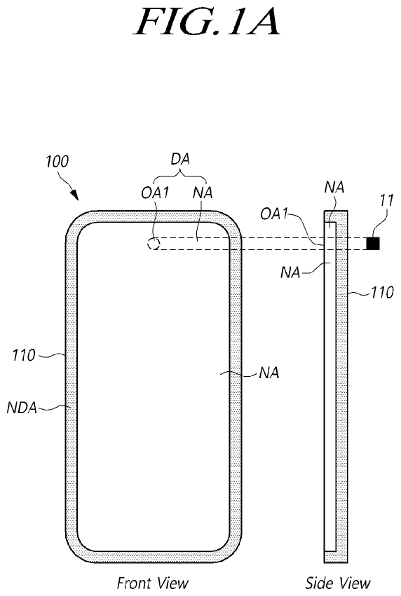

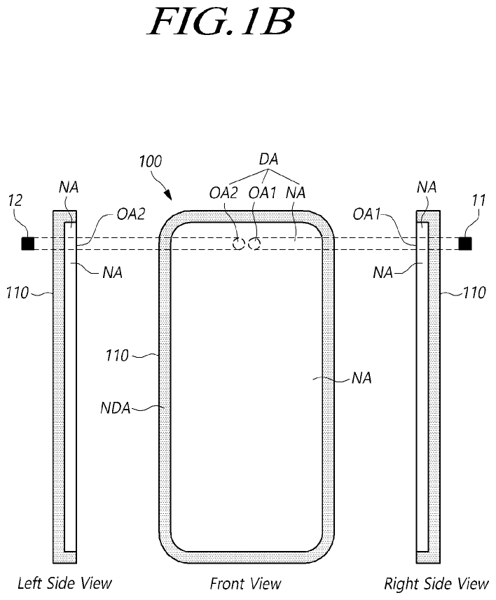

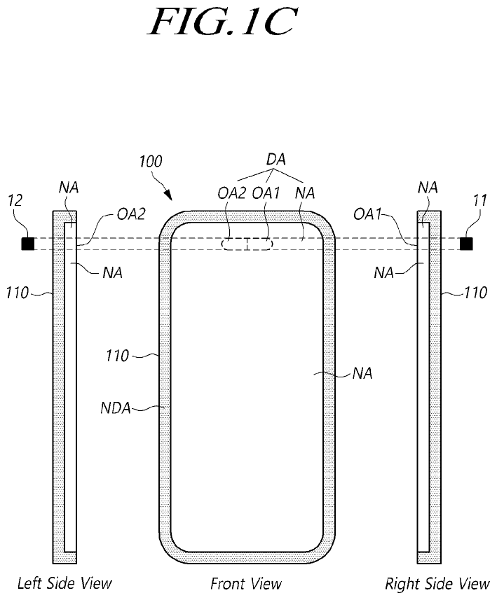

FIGS. 1A, 1B, and 1C illustrate an example display device 100 according to aspects of the present disclosure.

Referring to FIGS. 1A, 1B, and 1C, in one or more embodiments, the display device 100 according to aspects of the present disclosure may include a display panel 110 for displaying one or more images, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA in which one or more images can be displayed and a non-display area NDA in which an image is not displayed.

A plurality of subpixels may be arranged in the display area DA, and several types of signal lines for driving the plurality of subpixels may be arranged therein.

The non-display area NDA may refer to an area outside of the display area DA. Several types of signal lines may be arranged in the non-display area NDA, and several types of driving circuits may be connected thereto. At least a portion of the non-display area NDA may be bent to be invisible from the front surface of the display device 100 or may be covered by a case or housing (not shown) of the display device 100. The non-display area NDA may be also referred to as a bezel or a bezel area.

Referring to FIGS. 1A, 1B, and 1C, in one or more embodiments, in the display device 100 according to aspects of the present disclosure, one or more optical electronic devices (11 and/or 12) may be prepared independently of, and installed in, the display panel 110, and be located under, or in a lower portion of, the display panel 110 (an opposite side of a viewing surface thereof).

Light can enter the front surface (the viewing surface) of the display panel 110, pass through the display panel 110, reach one or more optical electronic devices (11 and/or 12) located under, or in the lower portion of, the display panel 110 (the opposite side of the viewing surface). Light transmitting through the display panel 110 may include, for example, visible light, infrared light, or ultraviolet light.

The one or more optical electronic devices (11 and/or 12) may be devices capable of receiving or detecting light transmitting through the display panel 110 and perform a predefined function based on the received light. For example, the one or more optical electronic devices (11 and/or 12) may include one or more of the following: an image capture device such as a camera (an image sensor), and/or the like; or a sensor such as a proximity sensor, an illuminance sensor, and/or the like. Such a sensor may be, for example, an infrared sensor capable of detecting infrared light.

Referring to FIGS. 1A, 1B, and 1C, in one or more embodiments, the display area DA of the display panel 110 according to aspects of the present disclosure may include one or more optical areas (OA1 and/or OA2) (a first area) and a normal area NA (a second area). Herein, the term “normal area” NA may represent an area that while being present in the display area DA, does not overlap one or more optical electronic devices (11 and/or 12) and may also be referred to as a non-optical area. The one or more optical areas (OA1 and/or OA2) may be one or more areas respectively overlapping the one or more optical electronic devices (11 and/or 12) in a cross-sectional view of the display panel 110.

According to an example of FIG. 1A, the display area DA may include a first optical area OA1 and a normal area NA. In this example, at least a portion of the first optical area OA1 may overlap a first optical electronic device 11.

According to an example of FIG. 1B, the display area DA may include a first optical area OA1, a second optical area OA2, and a normal area NA. In this example, a portion of the normal area NA may be present between the first optical area OA1 and the second optical area OA2. At least a portion of the first optical area OA1 may overlap the first optical electronic device 11, and at least a portion of the second optical area OA2 may overlap a second optical electronic device 12.

According to an example of FIG. 1C, the display area DA may include a first optical area OA1, a second optical area OA2, and a normal area NA. In this example, the normal area NA may not be present between the first optical area OA1 and the second optical area OA2. For example, the first optical area OA1 and the second optical area OA2 may contact each other (e.g., directly contact each other). In this example, at least a portion of the first optical area OA1 may overlap the first optical electronic device 11, and at least a portion of the second optical area OA2 may overlap the second optical electronic device 12.

In the display panel 110 or the display device 100 according to aspects of the present disclosure, it may be desirable that both an image display structure and a light transmission structure are implemented in the one or more optical areas (OA1 and/or OA2). For example, since the one or more optical areas (OA1 and/or OA2) are portions of the display area DA, it may be therefore desirable that light emitting areas of subpixels for displaying one or more images are disposed in the one or more optical areas (OA1 and/or OA2). Further, to enable light to be transmitted through the one or more optical electronic devices (11 and/or 12), it may be desirable that a light transmission structure is implemented in the one or more optical areas (OA1 and/or OA2).

It should be noted that even though the one or more optical electronic devices (11 and/or 12) are devices that need to receive light, the one or more optical electronic devices (11 and/or 12) may be located on the back of the display panel 110 (e.g., on an opposite side of the viewing surface thereof), and thereby, can receive light that has passed through the display panel 110. For example, the one or more optical electronic devices (11 and/or 12) may not be exposed in the front surface (viewing surface) of the display panel 110 or the display device 100. Accordingly, when a user faces the front surface of the display device 110, the one or more optical electronic devices (11 and/or 12) are located so that they cannot be visible to the user.

The first optical electronic device 11 may be, for example, a camera, and the second optical electronic device 12 may be, for example, a sensor. The sensor may be a proximity sensor, an illuminance sensor, an infrared sensor, and/or the like. In one or more embodiments, the camera may be a camera lens, an image sensor, or a unit including at least one of the camera lens and the image sensor, and the sensor may be an infrared sensor capable of detecting infrared light. In another embodiment, the first optical electronic device 11 may be a sensor, and the second optical electronic device 12 may be a camera.

Hereinafter, for convenience of descriptions related to the optical electronic devices (11 and 12), the first optical electronic device 11 is considered to be a camera, and the second optical electronic device 12 is considered to be an infrared sensor. It should be, however, understood that the scope of the present disclosure includes examples where the first optical electronic device 11 is an infrared sensor, and the second optical electronic device 12 is a camera. The camera may be, for example, a camera lens, an image sensor, or a unit including at least one of the camera lens and the image sensor.

In an example where the first optical electronic device 11 is a camera, this camera may be located on the back of (e.g., under, or in a lower portion of) the display panel 110, and be a front camera capable of capturing objects or images in a front direction of the display panel 110. Accordingly, the user can capture an image or object through the camera that is invisible on the viewing surface while looking at the viewing surface of the display panel 110.

Although the normal area NA and the one or more optical areas (OA1 and/or OA2) included in the display area DA in each of FIGS. 1A, 1B, and 1C are areas where images are allowed to be displayed, the normal area NA is an area where a light transmission structure need not be implemented, but the one or more optical areas (OA1 and/or OA2) are areas where a light transmission structure need be implemented. Thus, in one or more embodiments, the normal area NA is an area where a light transmission structure is not implemented or included, and the one or more optical areas (OA1 and/or OA2) are areas in which a light transmission structure is implemented or included.

Accordingly, the one or more optical areas (OA1 and/or OA2) can have a transmittance greater than or equal to a predetermined level (e.g., a relatively high transmittance) and the normal area NA can have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

In one embodiment, the number of subpixels per unit area in the one or more optical areas (OA1 and/or OA2) may be less than the number of subpixels per unit area in the normal area NA. For example, the resolution of the one or more optical areas (OA1 and/or OA2) may be lower than that of the normal area NA. In this example, the number of subpixels per unit area may have the same meaning as a resolution, a pixel density, or a degree of integration of pixels. For example, the unit of the number of subpixels per unit area may be pixels per inch (PPI), which represents the number of pixels within 1 inch.

In the examples of FIGS. 1A, 1B, and 1C, the number of subpixels per unit area in the first optical areas OA1 may be less than the number of subpixels per unit area in the normal area NA. In the examples of FIGS. 1B and 1C, the number of subpixels per unit area in the second optical areas OA2 may be greater than or equal to the number of subpixels per unit area in the first optical areas OA1, and be less than the number of subpixels per unit area in the normal area NA.

In one or more embodiments, as a method for increasing respective transmittance of at least one of the first optical area OA1 and the second optical area OA2, a pixel density differentiation design scheme as described above may be applied in which a difference in densities of pixels (or subpixels) or in degrees of integration of pixels (or subpixels) between the first optical area OA1, the second optical area OA2, and the normal area NA can be produced. According to the pixel density differentiation design scheme, in an embodiment, the display panel 110 may be configured or designed such that the number of subpixels per unit area of at least one of the first optical area OA1 and the second optical area OA2 is greater than the number of subpixels per unit area of the normal area NA.

In one or more embodiments, as another method for increasing respective transmittance of at least one of the first optical area OA1 and the second optical area OA2, a pixel size differentiation design scheme may be applied in which a difference in sizes of pixels (or subpixels) between the first optical area OA1, the second optical area OA2, and the normal area NA can be produced. According to the pixel size differentiation design scheme, the display panel PNL may be configured or designed such that while the number of subpixels per unit area of at least one of the first optical area OA1 and the second optical area OA2 is equal to or similar to the number of subpixels per unit area of the normal area NA, a size of each subpixel (i.e., a size of a corresponding light emitting area) disposed in at least one of the first optical area OA1 and the second optical area OA2 is smaller than a size of each subpixel (i.e., a size of a corresponding light emitting area) disposed in the normal area NA.

In one or more embodiments, for convenience of description, discussions that follow are provided based on the pixel density differentiation design scheme of the two schemes (i.e., the pixel density differentiation design scheme and the pixel size differentiation design scheme) for increasing respective transmittance of at least one of the first optical area OA1 and the second optical area OA2, unless explicitly stated otherwise. It should be therefore understood that in descriptions that follow, a small number of subpixels per unit area may be considered as corresponding to a small size of subpixel, and a large number of subpixels per unit area may be considered as corresponding to a large size of subpixel.

In the examples of FIGS. 1A, 1B, and 1C, the first optical area OA1 may have various shapes, such as a circle, an ellipse, a quadrangle, a hexagon, an octagon or the like. In the examples of FIGS. 1B and 1C, the second optical area OA2 may have various shapes, such as a circle, an ellipse, a quadrangle, a hexagon, an octagon or the like. The first optical area OA1 and the second optical area OA2 may have the same or substantially or nearly the same shape, or different shapes.

Referring to FIG. 1C, in the example where the first optical area OA1 and the second optical area OA2 contact each other (e.g., directly contact each other), the entire optical area including the first optical area OA1 and the second optical area OA2 may also have various shapes, such as a circle, an ellipse, a quadrangle, a hexagon, an octagon or the like. Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape.

According to one or more aspects of the present disclosure, when the display device 100 has a structure in which the first optical electronic device 11 such as a camera, and the like is located under, or in a lower portion of, the display panel 100 without being exposed to the outside, such a display device may be referred to as a display in which a under-display camera (UDC) technology is implemented.

The display device 100 in which such an under-display camera (UDC) technology is implemented can provide an advantage of preventing a reduction of an area or size of the display area DA because a notch or a camera hole for exposing a camera need not be formed in the display panel 110. Indeed, since a notch or a camera hole for camera exposure need not be formed in the display panel 110, the display device 100 can provide further advantages of reducing the size of a bezel area, and improving the degree of freedom in design because such limitations to the design are removed.

Although the one or more optical electronic devices (11 and/or 12) are located on the back of (e.g., under, or in a lower portion of) the display panel 110 of the display device 100 (e.g., hidden or not exposed to the outside), it is desirable that the one or more optical electronic devices (11 and/or 12) are able to perform their normal predefined functionalities by receiving or detecting light.

Further, although one or more optical electronic devices (11 and/or 12) are located on the back of (e.g., under, or in a lower portion of) the display panel 110 to be hidden and thus located to overlap the display area DA, it is desirable that the display device 100 is able to normally display one or more images in the one or more optical areas (OA1 and/or OA2) overlapping the one or more optical electronic devices (11 and/or 12) in the display area DA. Thus, even though one or more optical electronic devices (11 and/or 12) are located on the back of the display panel, the display device 100 according to aspects of the present disclosure can be configured to display images in a normal manner (e.g., without reduction in image quality) in the one or more optical areas (OA1 and/or OA2) overlapping the one or more optical electronic devices (11 and/or 12) in the display area DA.

Since the foregoing first optical area OA1 is configured or designed as an optically transmissive area, the quality of image display in the first optical area OA1 may be different from the quality of image display in the normal area NA.

Further, when designing the first optical area OA1 for the purpose of improving the quality of image display, there may be caused a situation that the transmittance of the first optical area OA1 is reduced.

To address these issues, in one or more aspects, the first optical area OA1 included in the display device 100 or the display panel may be configured with, or include, a structure capable of preventing or at least reducing a difference (e.g., non-uniformity) in image quality between the first optical area OA1 and the normal area NA from being caused, and improving the transmittance of the first optical area OA1.

Further, not only the first optical area OA1, but the second optical area OA2 included in the display device 100 or the display panel 110 according to aspects of the present disclosure may be configured with, or include, a structure capable of improving the image quality of the second optical area OA2, and improving the transmittance of the second optical area OA2.

It should be also noted that the first optical area OA1 and the second optical area OA2 included in the display device 100 or the display panel 110 according to aspects of the present disclosure may be differently implemented or have different utilization examples while having a similarity in terms of optically transmissive areas. Taking account of such a distinction, the structure of the first optical area OA1 and the structure of the second optical area OA2 in the display device 100 according to aspects of the present disclosure may be configured or designed differently from each other.

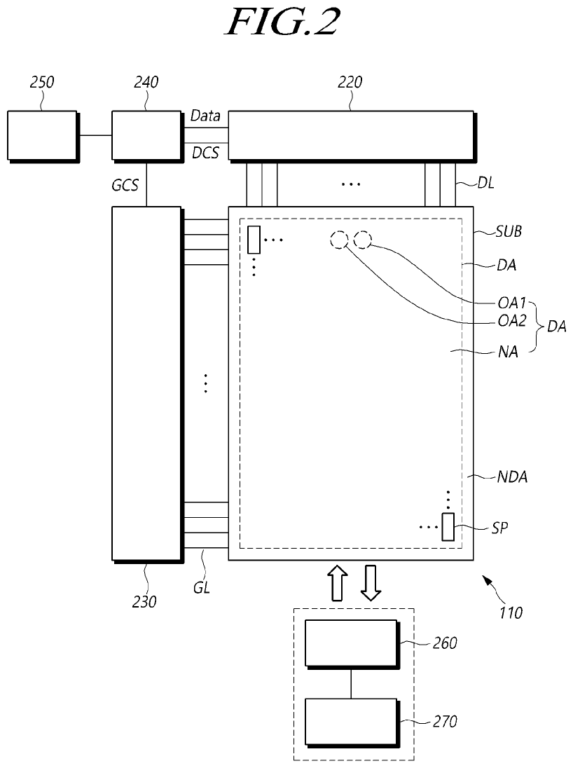

FIG. 2 illustrates an example system configuration of the display device 100 according to aspects of the present disclosure.

Referring to FIG. 2, the display device 100 may include the display panel 110 and a display driving circuit as components for displaying one or more images.

The display driving circuit may be a circuit for driving the display panel 110, and include a data driving circuit 220, a gate driving circuit 230, a display controller 240, and other circuit components.

The display panel 110 may include the display area DA in which one or more images can be displayed and a non-display area NDA in which an image is not displayed. The non-display area NDA may be an area outside of the display area DA, and may also be referred to as an edge area or a bezel area. All or at least a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB. The display panel 110 may further include various types of signal lines to drive the plurality of subpixels SP.

In one or more embodiments, the display device 100 according to aspects of the present disclosure may be a liquid crystal display device, or the like, or a self-emission display device in which light is emitted from the display panel 110 itself. In examples where the display device 100 according to aspects of the present disclosure is implemented as a self-emission display device, each of the plurality of subpixels SP may include a light emitting element. For example, the display device 100 according to aspects of the present disclosure may be an organic light emitting display device implemented with one or more organic light emitting diodes (OLED). In another example, the display device 100 according to aspects of the present disclosure may be an inorganic light emitting display device implemented with one or more inorganic material-based light emitting diodes. In further another example, the display device 100 according to aspects of the present disclosure may be a quantum dot display device implemented with quantum dots, which are self-emission semiconductor crystals.

The structure of each of the plurality of subpixels SP may be differently configured or designed according to types of the display devices 100. For example, in an example where the display device 100 is a self-emission display device including self-emission subpixels SP, each subpixel SP may include a self-emission light emitting element, one or more transistors, and one or more capacitors.

In one or more embodiments, various types of signal lines arranged in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another. Each of the plurality of data lines DL may extend in a first direction. Each of the plurality of gate lines GL may extend in a second direction different from the first direction. For example, the first direction may be a column or vertical direction, and the second direction may be a row or horizontal direction. In another example, the first direction may be the row or horizontal direction, and the second direction may be the column or vertical direction.

The data driving circuit 220 may be a circuit for driving the plurality of data lines DL, and can supply data signals to the plurality of data lines DL. The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data to the data driving circuit 220 based on the input image data.

The data driving circuit 220 can receive digital image data Data from the display controller 240, convert the received image data Data into analog data signals, and output the resulting analog data signals to the plurality of data lines DL.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more embodiments, the data driving circuit 220 may be connected to the display panel 110 in a tape automated bonding (TAB) type, or connected to a conductive pad such as a bonding pad of the display panel 110 in a chip on glass (COG) type or a chip on panel (COP) type, or connected to the display panel 110 in a chip on film (COF) type.

In one or more embodiments, the gate driving circuit 230 may be connected to the display panel 110 in the tape automated bonding (TAB) type, or connected to a conductive pad such as a bonding pad of the display panel 110 in the chip on glass (COG) type or the chip on panel (COP) type, or connected to the display panel 110 in the chip on film (COF) type. In another embodiment, the gate driving circuit 230 may be disposed in the non-display area NDA of the display panel 110 in a gate in panel (GIP) type. The gate driving circuit 230 may be disposed on the substrate, or connected to the substrate. That is, in the case of the GIP type, the gate driving circuit 230 may be disposed in the non-display area NDA of the substrate. In the case of the chip on glass (COG) type, the chip on film (COF) type, or the like, the gate driving circuit 230 may be connected to the substrate.

In one or more embodiments, at least one of the data driving circuit 220 and the gate driving circuit 230 may be disposed in the display area DA of the display panel 110. For example, at least one of the data driving circuit 220 and the gate driving circuit 230 may be disposed such that it does not overlap subpixels SP, or disposed such that it overlaps one or more, or all, of the subpixels SP, or at least respective one or more portions of one or more subpixels.

The data driving circuit 220 may be located in, and/or electrically connected to, but not limited to, only one side or portion (e.g., an upper edge or a lower edge) of the display panel 110. In one or more embodiments, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 230 may be located in, and/or electrically connected to, but not limited to, only one side or portion (e.g., a left edge or a right edge) of the display panel 110. In one or more embodiments, the gate driving circuit 230 may be located in, and/or electrically connected to, but not limited to, two sides or portions (e.g., a left edge and a right edge) of the panel 110 or at least two of four sides or portions (e.g., an upper edge, a lower edge, the left edge, and the right edge) of the panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more embodiments, the display controller 140 may be a controller or a control device different from the timing controller, or a circuitry or a component included in the controller or the control device. The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 220 and the data driving circuit 230 through the printed circuit board, flexible printed circuit, and/or the like.

The display controller 240 may transmit signals to, and receive signals from, the data driving circuit 220 via one or more predefined interfaces. For example, such interfaces may include a low voltage differential signaling (LVDS) interface, an embedded clock point-point interface (EPI), a serial peripheral interface (SPI), and the like.

In one or more embodiments, in order to further provide a touch sensing function, as well as an image display function, the display device 100 according to aspects of the present disclosure may include at least one touch sensor, and a touch sensing circuit capable of detecting whether a touch event occurs by a touch object such as a finger, a pen, or the like, or of detecting a corresponding touch position (or touch coordinates), by sensing the touch sensor.

The touch sensing circuit may include: a touch driving circuit 260 capable of generating and providing touch sensing data by driving and sensing the touch sensor; a touch controller 270 capable of detecting the occurrence of a touch event or detecting a touch position (or touch coordinates) using the touch sensing data; and one or more other components.

The touch sensor may include a plurality of touch electrodes. The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing using a self-capacitance sensing technique or a mutual-capacitance sensing technique.

In the example where the touch sensing circuit performs touch sensing using the self-capacitance sensing technique, the touch sensing circuit can perform touch sensing based on capacitance between each touch electrode and a touch object (e.g., a finger, a pen, and the like). According to the self-capacitance sensing technique, each of the plurality of touch electrodes can serve as both a driving touch electrode and a sensing touch electrode. The touch driving circuit 260 can drive all, or one or more, of the plurality of touch electrodes and sense all, or one or more, of the plurality of touch electrodes.

In the example where the touch sensing circuit performs touch sensing using the mutual-capacitance sensing technique, the touch sensing circuit can perform touch sensing based on capacitance between touch electrodes. According to the mutual-capacitance sensing technique, the plurality of touch electrodes are divided into driving touch electrodes and sensing touch electrodes. The touch driving circuit 260 can drive the driving touch electrodes and sense the sensing touch electrodes.

The touch driving circuit 260 and the touch controller 270 included in the touch sensing circuit may be implemented in separate devices or in a single device. Further, the touch driving circuit 260 and the data driving circuit 220 may be implemented in separate devices or in a single device.

The display device 100 may further include a power supply circuit for supplying various types of power to the display driving circuit and/or the touch sensing circuit.

The display device 100 according to aspects of the present disclosure may represent, but not limited to, a mobile terminal such as a smart phone, a tablet, or the like, a monitor, a television (TV), or the like. Embodiments of the present disclosure are not limited thereto. In one or more embodiments, the display device 100 may be display devices, or include displays, of various types, sizes, and shapes for displaying information or images.

As described above, the display area DA of the display panel 110 may include the normal area NA and the one or more optical areas (OA1 and/or OA2) as illustrated in FIGS. 1A, 1B, and 1C. The normal area NA and the one or more optical areas (OA1 and/or OA2) may be areas where images can be displayed. It should be noted here that the normal NA may be an area in which a light transmission structure need not be implemented, and the one or more optical areas (OA1 and/or OA2) may be areas in which a light transmission structure need be implemented.

As discussed above with respect to the examples of FIGS. 1A, 1B, and 1C, even though the display area DA of the display panel 110 may include the one or more optical areas (OA1 and/or OA2) together with the normal area NA, for convenience of description, discussions that follow will be provided based on examples where the display area DA includes both the first and second optical areas OA1 and OA2 (i.e., the first optical area OA1 of FIGS. 1A, 1B, and 1C, and the second optical area OA2 of FIGS. 1B and 1C) and the normal area NA (i.e., the normal area NA of FIGS. 1A, 1B, and 1C).

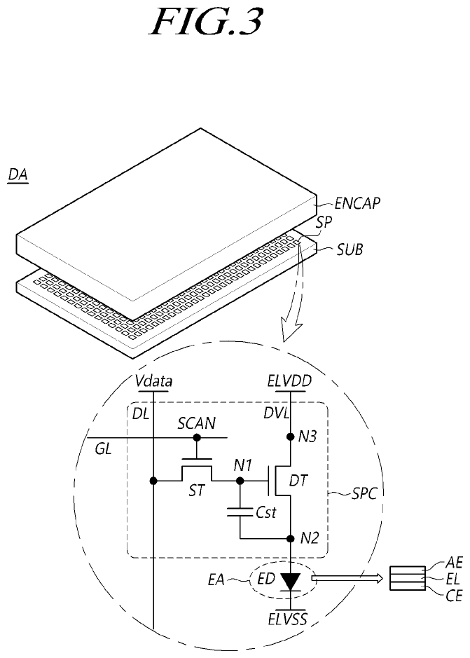

FIG. 3 illustrates an example system configuration of the display device 110 according to aspects of the present disclosure.

Referring to FIG. 3, a plurality of subpixels SP may be disposed in the display area DA of the display panel 110. The plurality of subpixels SP may be disposed in a normal area (e.g., the normal area of FIGS. 1A, 1B, and 1C), a first optical area (e.g., the first optical area OA1 of FIGS. 1A, 1B, and 1C), and a second optical area (e.g., the second optical area OA2 of FIGS. 1B and 1C) included in the display area DA of the display panel 110.

Referring to FIG. 3, each of the plurality of subpixels SP may include a light emitting element ED and a pixel circuit SPC configured to drive the light emitting element ED.

Referring to FIG. 3, the pixel circuit SPC may include a driving transistor DT for driving the light emitting element ED, a scan transistor ST for transferring a data voltage Vdata to a first node N1 of the driving transistor DT, a storage capacitor Cst for maintaining a voltage at an approximate constant level during one frame, and the like.

The driving transistor DT may include the first node N1 to which a data voltage is applied, a second node N2 electrically connected to the light emitting element ED, and a third node N3 to which a driving voltage ELVDD through a driving voltage line DVL is applied. In the driving transistor DT, the first node N1 may be a gate node, the second node N2 may be a source node or a drain node, and the third node N3 may be the drain node or the source node. For convenience of description, descriptions that follow will be provided based on examples where the first, second and third nodes (N1, N2 and N3) of the driving transistor DT are gate, source and drain nodes, respectively, unless explicitly stated otherwise. However, it should be understood that the scope of the present disclosure includes examples where the first, second and third nodes (N1, N2 and N3) of the driving transistor DT are gate, drain and source nodes, respectively.

The light emitting element ED may include an anode electrode AE, an emission layer EL, and a cathode electrode CE. The anode electrode AE may represent a pixel electrode disposed in each subpixel SP, and may be electrically connected to the second node N2 of the driving transistor DT of each subpixel SP. The cathode electrode CE may represent a common electrode being disposed in the plurality of subpixels SP in common, and a base voltage ELVSS such as a low-level voltage, a ground voltage, or the like may be applied to the cathode electrode CE.

For example, the anode electrode AE may be a pixel electrode, and the cathode electrode CE may be a common electrode. In another example, the anode electrode AE may be a common electrode, and the cathode electrode CE may be a pixel electrode. For convenience of description, discussions that follow will be provided based on examples where the anode electrode AE is a pixel electrode, and the cathode electrode CE is a common electrode unless explicitly stated otherwise. However, it should be understood that the scope of the present disclosure includes examples where the anode electrode AE is a common electrode, and the cathode electrode CE is a pixel electrode.

The light emitting element ED may include a light emitting area EA having a predetermined size or area. The light emitting area EA of the light emitting element ED may be defined as, for example, an area in which the anode electrode AE, the emission layer EL, and the cathode electrode CE overlap one another.

The light emitting element ED may be, for example, an organic light emitting diode (OLED), an inorganic light emitting diode, a quantum dot light emitting element, or the like. In the example where an organic light emitting diode (OLED) is used as the light emitting element ED, the emission layer EL thereof may include an organic emission layer including an organic material.

The scan transistor ST can be turned on and off by a scan signal SCAN, which is a gate signal applied through a gate line GL, and be electrically connected between the first node N1 of the driving transistor DT and a data line DL.

The storage capacitor Cst may be electrically connected between the first node N1 and the second node N2 of the driving transistor DT.

The pixel circuit SPC may be configured with two transistors (2T: DRT and SCT) and one capacitor (1C: Cst) (which may be referred to as a “2T1C structure”) as shown in FIG. 3, and in one or more implementations, may further include one or more transistors, and/or further include one or more capacitors.

In one or more embodiments, the storage capacitor Cst, which may be present between the first node N1 and the second node N2 of the driving transistor DT, may be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like). Each of the driving transistor DT and the scan transistor ST may be an n-type transistor or a p-type transistor.

Since circuit elements (in particular, a light emitting element ED implemented with an organic light emitting diode including an organic material) included in each subpixel SP are vulnerable to external moisture or oxygen, an encapsulation layer ENCAP may be disposed in the display panel 110 in order to prevent external moisture or oxygen from penetrating into such circuit elements. The encapsulation layer ENCAP may be disposed such that it covers the light emitting element ED.

Hereinafter, for convenience of description, the term “optical area OA” is used instead of distinctly describing the first optical area OA1 and the second optical area OA2 described above. Thus, it should be noted that an optical area described below may represent any one or both of the first and second optical area OA1 and OA2 described above, unless explicitly stated otherwise.

Likewise, for convenience of description, the term “optical electronic device” is used instead of distinctly describing the first optical electronic device 11 and the second optical electronic device 12 described above. Thus, it should be noted that an optical electronic device described below may represent any one or both of the first and second optical electronic device 11 and 12 described above, unless explicitly stated otherwise.

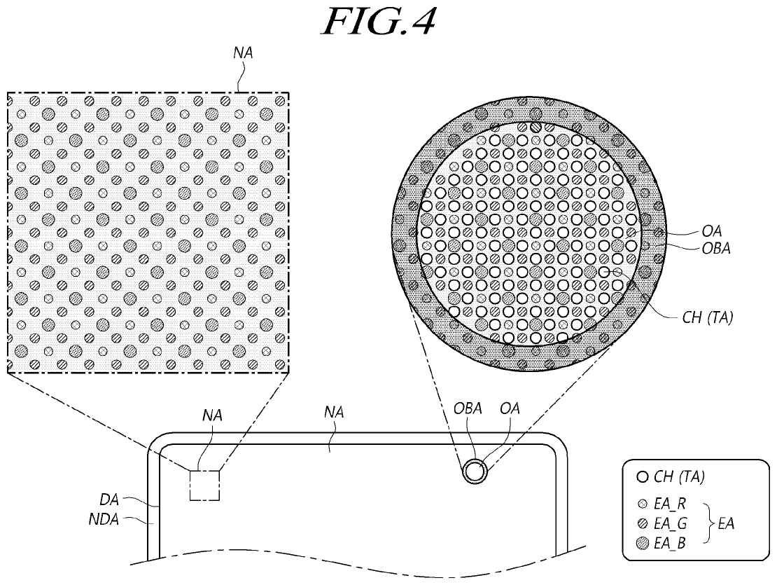

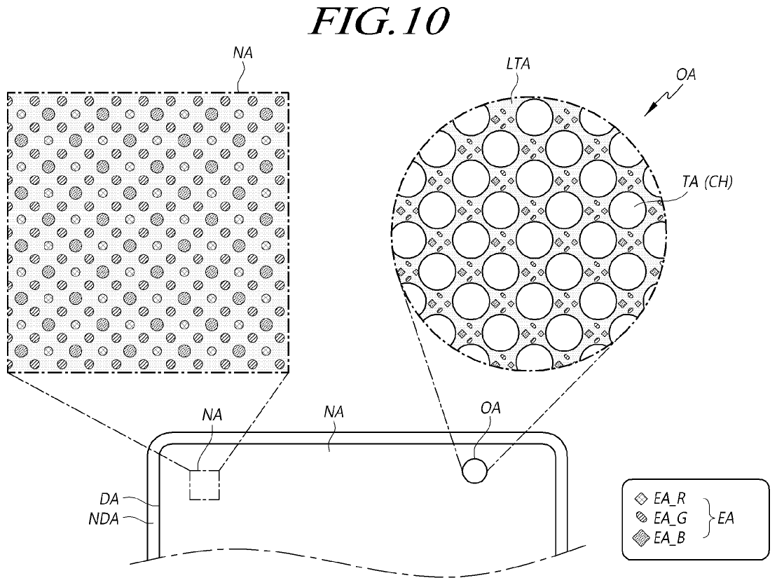

Hereinafter, an example first type of optical area OA will be described with reference to FIGS. 4 to 9, and an example second type of optical area OA will be described with reference to FIGS. 10 to 12.

The first type of optical area OA and the second type of optical area OA are briefly described as follows.

In the case of the first type of optical area OA, one or more pixel circuits SPC for driving one or more light emitting elements ED disposed in the optical area OA may be disposed in an area outside of the optical area OA without being in the optical area OA.

In the case of the second type of optical area OA, one or more pixel circuits SPC for driving one or more light emitting elements ED disposed in the optical area OA may be disposed the optical area OA.

FIG. 4 schematically illustrates an example first type of optical area OA and an example normal area NA around the first type of optical area OA in the display panel 110 according to aspects of the present disclosure.

Referring to FIG. 4, in one or more embodiments, the display panel 110 according to aspects of the present disclosure may include a display area (e.g., the display area DA of figures described above) where one or more images can be displayed and a non-display area (e.g., the non-display area NDA of figures described above) where an image is not displayed.

Referring to FIG. 4, the display area DA may include an optical area OA through which light can be transmitted, and a normal area NA around the optical area OA.

The optical area OA may have the structure of a first type. Thus, in an example where the optical area OA is implemented in the first type, an optical bezel area OBA may be disposed outside of the optical area OA. In one or more embodiments, the optical bezel area OBA may represent a part of the normal area NA.

In other words, when the optical area OA is implemented in the first type, the display area DA may include the optical area OA, the normal area NA located outside of the optical area OA, and the optical bezel area OBA between the optical area OA and the normal area NA.

Referring to FIG. 4, the optical area OA may be an area overlapping an optical electronic device and be a transmissive area through which light used for operation of the optical electronic device can be transmitted.

The light transmitting through the optical area OA may include light of a single wavelength band or light of various wavelength bands. For example, the optical area OA may be configured to allow, but not limited to, at least one of visible light, infrared light, ultraviolet light, and the like to be transmitted.

An optical electronic device disposed in the optical area OA can receive light transmitting through the optical area OA and perform a predefined operation using the received light. The light received by the optical electronic device through the optical area OA may include at least one of visible light, infrared light, and ultraviolet light.

For example, in an example where the optical electronic device is a camera, the light used for the predefined operation of the optical electronic device, which has passed through the optical area OA, may include visible light.

In another example, in an example where the optical electronic device is an infrared sensor, the light used for the predefined operation of the optical electronic device, which has passed through the optical area OA, may include infrared (also referred to as infrared light).

Referring to FIG. 4, the optical bezel area OBA may represent an area located outside of the optical area OA. The normal area NA may represent an area located outside of the optical bezel area OBA. The optical bezel area OBA may be disposed between the optical area OA and the normal area NA.

For example, the optical bezel area OBA may be disposed outside of a portion of an edge of the optical area OA, or disposed outside of the entire edge of the optical area OA.

In the example where the optical bezel area OBA is disposed outside of the entire edge of the optical area OA, the optical bezel area OBA may have a ring shape surrounding the optical area OA.

For example, the optical area OA may have various shapes such as a circular shape, an elliptical shape, a polygonal shape, an irregular shape, or the like. The optical bezel area OBA may have various ring shapes (e.g., a circular ring shape, an elliptical ring shape, a polygonal ring shape, an irregular ring shape, or the like) surrounding the optical area OA having various shapes.

Referring to FIG. 4, the display area DA may include a plurality of light emitting areas EA. Since the optical area OA, the optical bezel area OBA, and the normal area NA are areas included in the display area DA, each of the optical area OA, the optical bezel area OBA, and the normal area NA may include a plurality of light emitting areas EA.

For example, the plurality of light emitting areas EA may include one or more first color light emitting areas emitting light of a first color, one or more second color light emitting areas emitting light of a second color, and one or more third color light emitting areas emitting light of a third color.

At least one of the first color light emitting area, the second color light emitting area, and the third color light emitting area may have a different area or size from the remaining one or more light emitting areas.

The first color, the second color, and the third color may be different colors from one another, and may be various colors. For example, the first color, second color, and third color may be or include red, green, and blue, respectively.

Hereinafter, for convenience of description, the first color, the second color, and the third color are considered to be red, green, and blue, respectively. However, embodiments of the present disclosure are not limited thereto.

In the example where the first color, the second color, and the third color are red, green, and blue, respectively, an area of a blue light emitting area EA_B may be greater than an area of a red light emitting area EA_R and an area of a green light emitting area EA_G.

A light emitting element ED disposed in the red light emitting area EA_R may include an emission layer EL emitting red light. A light emitting element ED disposed in the green light emitting area EA_G may include an emission layer EL emitting green light. A light emitting element ED disposed in the blue light emitting area EA_B may include an emission layer EL emitting blue light.

An organic material included in the emission layer EL emitting blue light may be more easily degraded in terms of material than respective organic materials included in the emission layer EL emitting red light and the emission layer EL emitting green light.

In one or more embodiments, as the blue light emitting area EA_B is configured or designed to have the largest area or size, current density supplied to the light emitting element ED disposed in the blue light emitting area EA_B may be the least. Therefore, a degradation degree of a light emitting element ED disposed in the blue light emitting area EA_B may be similar to a degradation degree of a light emitting element ED disposed in the red light emitting area EA_R and a degradation degree of a light emitting element ED disposed in the green light emitting area EA_G.

In consequence, a difference in degradation between the light emitting element ED disposed in the red light emitting area EA_R, the light emitting elements ED disposed in the green light emitting area EA_G, and the light emitting elements ED disposed in the blue light emitting area EA_B cannot be produced or can be reduced, and therefore, the display device 100 or the display panel 110 according to embodiments of the present disclosure can provide an advantage of improving image quality. In addition, as a difference in degradation between the light emitting element ED disposed in the red light emitting area EA_R, the light emitting elements ED disposed in the green light emitting area EA_G, and the light emitting elements ED disposed in the blue light emitting area EA_B is eliminated or reduced, the display device 100 or the display panel 110 according to aspects of the present disclosure can therefore provide an advantage of reducing a difference in lifespan between the light emitting element ED disposed in the red light emitting area EA_R, the light emitting elements ED disposed in the green light emitting area EA_G, and the light emitting elements ED disposed in the blue light emitting area EA_B.

Referring to FIG. 4, the optical area OA, which is an optically transmissive area, has high transmittance. To meet this requirement, a cathode electrode (e.g., the cathode electrode CE of FIG. 3) may include a plurality of cathode holes CH in the optical area OA. That is, in the optical area OA, the cathode electrode CE may include a plurality of cathode holes CH.

Referring to FIG. 4, in one or more embodiments, the cathode electrode CE may not include a cathode hole CH in the normal area NA. That is, in the normal area NA, the cathode electrode CE may not include a cathode hole CH.

In one or more embodiments, the cathode electrode CE may not include a cathode hole CH in the optical bezel area OBA. That is, in the optical bezel area OBA, the cathode electrode CE may not include a cathode hole CH.

In the optical area OA, the plurality of cathode holes CH formed in the cathode electrode CE may be referred to as a plurality of transmissive areas TA or a plurality of openings. Although FIG. 4 illustrates that each cathode hole CH has a respective circular shape, one or more cathode holes CH may have various shapes other than the circular shape, such as an elliptical shape, a polygonal shape, an irregular shape or the like.

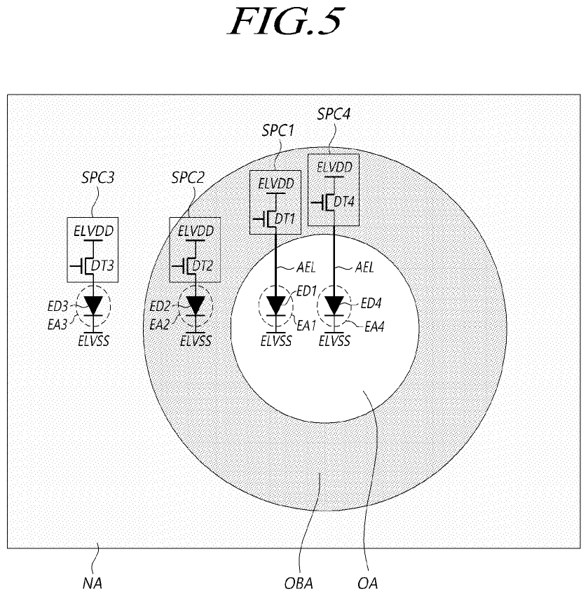

FIG. 5 illustrates an example configuration of the display panel 110 according to aspects of the present disclosure. As illustrated in FIG. 5, the display panel 110 may include light emitting elements (ED1, ED2, ED3, and ED4) disposed in the normal area NA, the optical bezel area OBA, and the optical area OA, and pixel circuits (SPC1, SPC2, SPC3, and SPC4) for driving the light emitting elements (ED1, ED2, ED3, and ED4).

It should be understood here that each of the pixel circuits (SPC1, SPC2, SPC3, and SPC4) may include transistors (DT and ST), a storage capacitor Cst, and the like as shown in FIG. 3. However, it should be noted that for convenience of explanation, each of the pixel circuits (SPC1, SPC2, SPC3, and SPC4) is simply expressed as only a respective driving transistor (DT1, DT2, DT3, and DT4).

Referring to FIG. 5, the normal area NA, the optical area OA, and the optical bezel area OBA may have structural differences as well as positional differences.

As one example of such structural differences, one or more pixel circuits (SPC1, SPC2, SPC3, and/or SPC4) may be disposed in the optical bezel area OBA and the normal area NA, but a pixel circuit may not be disposed in the optical area OA. For example, the optical bezel area OBA and the normal area NA may be configured to allow one or more transistors (DT1, DT2, DT3, and/or DT4) to be disposed therein, but the optical area OA may be configured not to allow a transistor to be disposed therein.

Transistors and storage capacitors included in the pixel circuits (SPC1, SPC2, SPC3, and SPC4) may be components causing transmittance to be reduced. Thus, since a pixel circuit (e.g., SPC1, SPC2, SPC3, or SPC4) is not disposed in the optical area OA, the transmittance of the optical area OA can be more improved.

In one or more embodiments, although the pixel circuits (SPC1, SPC2, SPC3, and SPC4) may be disposed only in the normal area NA and the optical bezel area OBA, the light emitting elements (ED1, ED2, ED3, and ED4) may be disposed in the normal area NA, the optical bezel area OBA, and the optical area OA.

Referring to FIG. 5, although a first light emitting element ED1 may be disposed in the optical area OA, a first pixel circuit SPC1 for driving the first light emitting element ED1 may not be located in the optical area OA.

Referring to FIG. 5, the first pixel circuit SPC1 for driving the first light emitting element ED1 disposed in the optical area OA may be disposed in the optical bezel area OBA, not in the optical area OA.

Hereinafter, the normal area NA, the optical area OA, and the optical bezel area OBA will be described in more detail.

Referring to FIG. 5, in one or more embodiments, the plurality of light emitting areas EA included in the display panel 110 according to aspects of the present disclosure may include a first light emitting area EA1, a second light emitting area EA2, and a third light emitting area EA3. In these embodiments, the first light emitting area EA1, the second light emitting area EA2, and the third light emitting area EA3 may be included in the optical area OA, the optical bezel area OBA, and the normal area NA, respectively. Hereinafter, it is assumed that the first light emitting area EA1, the second light emitting area EA2, and the third light emitting area EA3 are areas emitting light of a same color.

Referring to FIG. 5, in one or more embodiments, the display panel 110 according to aspects of the present disclosure may include: a first light emitting element ED1 disposed in the optical area OA1 and having the first light emitting area EA1; a second light emitting element ED2 disposed in the optical bezel area OBA1 and having the second light emitting area EA2; and a third light emitting element ED3 disposed in the normal area NA and having the third light emitting area EA3.

Referring to FIG. 5, in one or more embodiments, the display panel 110 according to aspects of the present disclosure may further include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

Referring to FIG. 5, the first pixel circuit SPC1 may include a first driving transistor DT1. The second pixel circuit SPC2 may include a second driving transistor DT2. The third pixel circuit SPC3 may include a third driving transistor DT3.

Referring to FIG. 5, in one or more embodiments, in the display panel 110 according to aspects of the present disclosure, the second pixel circuit SPC2 may be located in the optical bezel area OBA where the second light emitting element ED2 corresponding to the second pixel circuit SPC2 is disposed, and the third pixel circuit SPC3 may be located in the normal area NA where the third light emitting element ED3 corresponding to the third pixel circuit SPC3 is disposed.

Referring to FIG. 5, in one or more embodiments, in the display panel 110 according to aspects of the present disclosure, the first pixel circuit SPC1 may not be located in the optical area OA where the first light emitting element ED1 corresponding to the first pixel circuit SPC1 is disposed. Instead, the first pixel circuit SPC1 may be located in the optical bezel area OBA located outside of the optical area OA. As a result, the transmittance of the optical area OA can be improved.

Referring to FIG. 5, in one or more embodiments, the display panel 110 according to aspects of the present disclosure may further include an anode extension line AEL electrically connecting the first light emitting element ED1 disposed in the optical area OA to the first pixel circuit SPC1 disposed in the optical bezel area OBA.

The anode extension line AEL may electrically extend or connect an anode electrode AE of the first light emitting element ED1 to a second node N2 of the first driving transistor DT1 in the first pixel circuit SPC1.

As described above, in the display panel 110 according to aspects of the present disclosure, the first pixel circuit SPC1 for driving the first light emitting element ED1 disposed in the optical area OA may be disposed in the optical bezel area OBA, not in the optical area OA. Such a structure may be referred to as an anode extension structure. Likewise, the first type of the optical area OA may be also referred to as an anode extension type.

In an embodiment where the display panel 110 according to aspects of the present disclosure has such an anode extension structure, all or at least a portion of the anode extension line AEL may be disposed in optical area OA, and the anode extension line AEL may include a transparent material, or be or include a transparent line. Accordingly, even when the anode extension line AEL for connecting the first pixel circuit SPC1 to the first light emitting element ED1 is disposed in the optical area OA, the display device or the display panel 110 according to aspects of the present disclosure can prevent the transmittance of the optical area OA from being reduced.

Referring to FIG. 5, a plurality of light emitting areas EA may further include a fourth light emitting area EA4 emitting light of the same color as the first light emitting area EA1 and included in the optical area OA.

Referring to FIG. 5, the fourth light emitting area EA4 may be disposed adjacent to the first light emitting area EA1 in a row direction or a column direction.

Referring to FIG. 5, in one or more embodiments, the display panel 110 according to aspects of the present disclosure may further include a fourth light emitting element ED4 disposed in the optical area OA and having the fourth light emitting area EA4, and a fourth pixel circuit SPC4 configured to drive the fourth light emitting element ED4.

Referring to FIG. 5, the fourth pixel circuit SPC4 may include a fourth driving transistor DT4. For convenience of description, a scan transistor ST and a storage capacitor Cst included in the fourth pixel circuit SPC4 are omitted from FIG. 5.

Referring to FIG. 5, although the fourth pixel circuit SPC4 is a circuit for driving the fourth light emitting element ED4 disposed in the optical area OA, the fourth pixel circuit SPC4 may be disposed in the optical bezel area OBA.

Referring to FIG. 5, in one or more embodiments, the display panel 110 according to aspects of the present disclosure may further include an anode extension line AEL for electrically connecting the fourth light emitting element ED4 to the fourth pixel circuit SPC4.

All or at least a portion of the anode extension line AEL may be disposed in the optical area OA, and the anode extension line AEL may include a transparent material, or be or include a transparent line.

As described above, the first pixel circuit SPC1 disposed in the optical bezel area OBA may be configured to drive one light emitting element ED1 disposed in the optical area OA. Such a circuit connection scheme may be referred to as a one-to-one (1:1) circuit connection scheme.

As a result, the number of pixel circuits SPC disposed in the optical bezel area OBA may be increased significantly. Further, the structure of the optical bezel area OBA may become complicated, and an open area of the optical bezel area OBA may be reduced. Herein, the open area may be referred to as a light emitting area, and may also be referred to as an open ratio or an aperture ratio.

In order to increase an open area of the optical bezel area OBA while having an anode extension structure, in one or more embodiments, the display device 100 according to aspects of the present disclosure may be configured in a 1:N (where N is 2 or more) circuit connection scheme.

According to the 1:N circuit connection scheme, the first pixel circuit SPC1 disposed in the optical bezel area OBA may be configured to drive two light emitting elements ED disposed in the optical area OA concurrently or together.

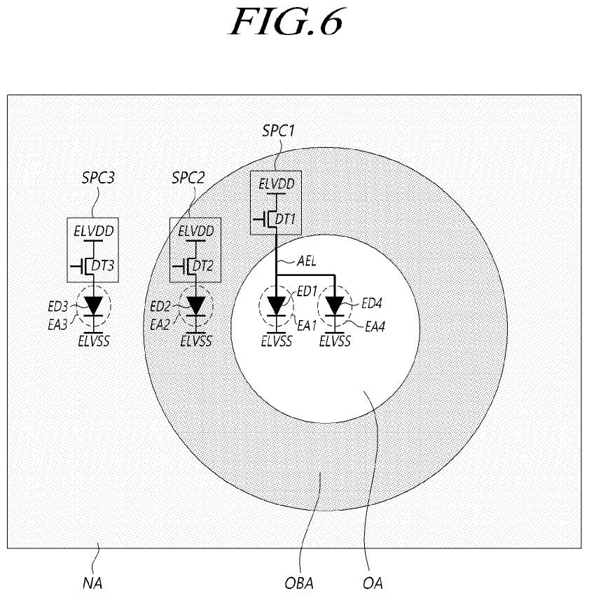

FIG. 6 illustrates a 1:2 circuit connection scheme as an example for convenience of description. In this example, a first pixel circuit SPC1 disposed in the optical bezel area OBA may be configured to drive two or more light emitting elements (ED1 and ED4) disposed in the optical area OA concurrently or together.

In one or more embodiments, referring to FIG. 6, light emitting elements (ED1, ED2, ED3, and ED4) disposed in the normal area NA, the optical bezel area OBA, and the optical area OA, and pixel circuits (SPC1, SPC2, and SPC3) for driving the light emitting elements (ED1, ED2, ED3, and ED4) may be disposed in the display panel 110.

Referring to FIG. 6, a fourth light emitting element ED4 disposed in the optical area OA can be driven by the first pixel circuit SPC1 for driving a first light emitting element ED1 located in the optical area OA. That is, the first pixel circuit SPC1 disposed in the optical bezel area OBA may be configured to drive the first light emitting element ED1 and the fourth light emitting element ED4 disposed in the optical area OA together or substantially concurrently.

Accordingly, even when the display panel 110 has an anode extension structure, the number of pixel circuits SPC disposed in the optical bezel area OBA can be significantly reduced, and thereby, an open area and a light emitting area of the optical bezel area OBA can be increased.

In the example of FIG. 6, the first light emitting element ED1 and the fourth light emitting element ED4 driven together by the first pixel circuit SPC1 disposed in the optical bezel area OBA may be light emitting elements that emit light of a same color, and are adjacent to each other in a row direction or a column direction.

Referring to FIG. 6, an anode extension line AEL may connect the first light emitting element ED1 and the fourth light emitting element ED4 disposed in the optical area OA to the first pixel circuit SPC1 disposed in the optical bezel area OBA.

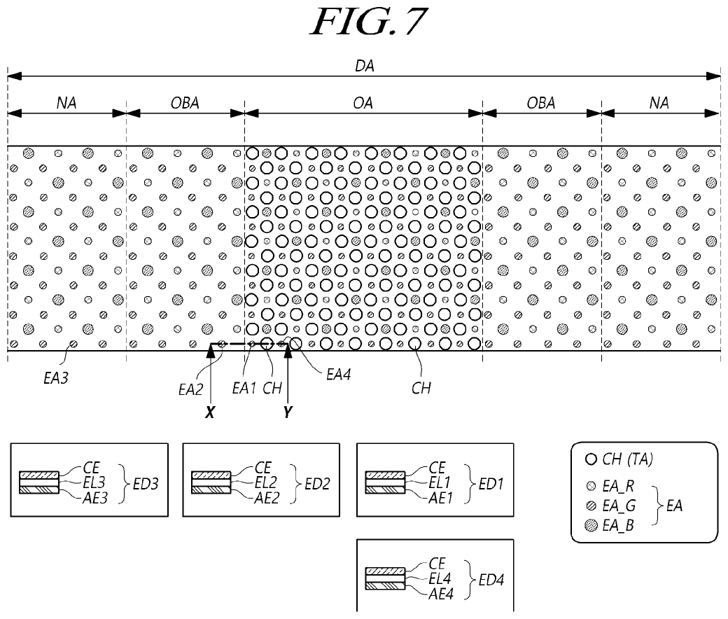

FIG. 7 is an example plan view of the normal area NA, the optical bezel area OBA, and the optical area OA in the display panel 110 according to embodiments of the present disclosure.

Referring to FIG. 7, in one or more embodiments, in the display panel 110 according to aspects of the present disclosure, a plurality of light emitting areas EA disposed in each of the normal area NA, the optical bezel area OBA, and the optical area OA may include one or more red light emitting areas EA_R, one or more green light emitting areas EA_G, and one or more blue light emitting areas EA_B.

Referring to FIG. 7, in one or more embodiments, in the display panel 110 according to aspects of the present disclosure, a cathode electrode (e.g., the cathode electrode CE of FIG. 3) may be commonly disposed in the normal area NA, the optical bezel area OBA, and the optical area OA.

The cathode electrode CE may include a plurality of cathode holes CH, and the plurality of cathode holes CH of the cathode electrode CE may be disposed in the optical area OA.

The normal area NA and the optical bezel area OBA may be areas allowing light not to be transmitted, and the optical area OA may be an area allowing light to be transmitted. Accordingly, the transmittance of the optical area OA may be higher than respective transmittance of the optical bezel area OBA and the normal area NA.

For example, all of the optical area OA may be an area through which light can be transmitted, and the plurality of cathode holes CH of the optical area OA may be transmissive areas TA through which light can be transmitted more effectively. That is, the remaining area except for the plurality of cathode holes CH in the optical area OA may be an area through which light can be transmitted, and respective transmittance of the plurality of cathode holes CH in the optical area OA may be higher than the transmittance of the remaining area except for the plurality of cathode holes (CH) in the optical area OA.

In another example, the plurality of cathode holes CH in the optical area OA may be transmissive areas TA through which light can be transmitted, and the remaining area except for the plurality of cathode holes CH in the optical area OA may be an area through which light cannot be transmitted.

Referring to FIG. 7, the arrangement of light emitting areas EA in the optical area OA, the arrangement of light emitting areas EA in the optical bezel area OBA, and the arrangement of light emitting areas EA in the normal area NA may be the same as one another.

Referring to FIG. 7, a plurality of light emitting areas EA may include one or more first light emitting areas EA1 included in the optical area OA, one or more second light emitting areas EA2 included in the optical bezel area OBA and emitting light of the same color as the one or more first light emitting areas EA1, and one or more third light emitting areas EA3 included in the normal area NA and emitting light of the same color as the one or more first light emitting areas EA1.

Referring to FIG. 7, the plurality of light emitting areas EA may further include one or more fourth light emitting area EA4 included in the optical area OA and emitting light of the same color as the one or more first light emitting areas EA1.

Referring to FIG. 7, in one or more embodiments, the display panel 110 according to aspects of the present disclosure may include one or more first anode electrodes AE1 disposed in the optical area OA, one or more second anode electrodes AE2 disposed in the optical bezel area OBA, one or more third anode electrodes AE3 disposed in the normal area NA, and one or more fourth anode electrodes AE4 disposed in the optical area OA.

In one or more embodiments, the display panel 110 according to aspects of the present disclosure may further include a cathode electrode (e.g., the cathode electrode CE in FIG. 3) commonly disposed in the normal area NA, the optical bezel area OBA, and the optical area OA.

In one or more embodiments, the display panel 110 according to aspects of the present disclosure may include one or more first emission layers EL1 disposed in the optical area OA, one or more second emission layers EL2 disposed in the optical bezel area OBA, one or more third emission layers EL3 disposed in the normal area NA, and one or more fourth emission layers EL4 disposed in the optical area OA.

The first to fourth emission layers EL4 may be emission layers emitting light of a same color. In these embodiments, the first to fourth emission layers EL1 to EL4 may be disposed as separate emission layers or be integrated into a single emission layer.

Referring to FIG. 7, light emitting elements of the display panel 110 according to aspects of the present disclosure may be configured such that: the first light emitting element ED1 is configured with the first anode electrode AE1, the first emission layer EL1, and the cathode electrode CE; the second light emitting element ED2 is configured with the second anode electrode AE2, the second emission layer EL2, and the cathode electrode CE; the third light emitting element ED3 is configured with the third anode electrode AE3, the third emission layer EL3, and the cathode electrode CE; and the fourth light emitting element ED4 is configured with the fourth anode electrode AE4, the fourth emission layer EL4, and the cathode electrode CE.

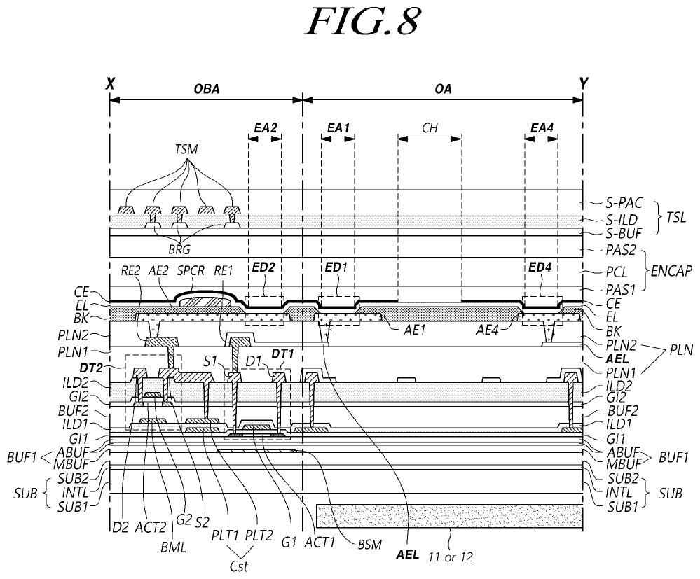

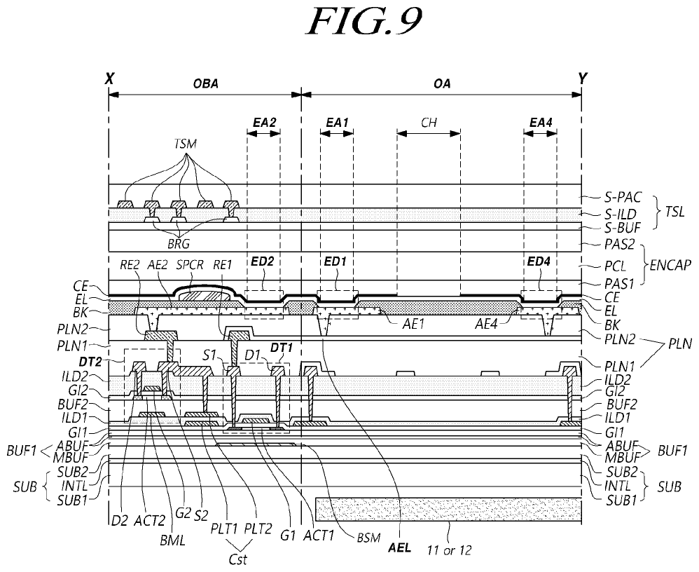

Hereinafter, a cross-sectional structure taken along line X-Y of FIG. 7 will be discussed in more detail with reference to FIGS. 8 and 9.

A portion indicated by line X-Y in FIG. 7 includes a portion of the optical bezel area OBA1 and a portion of the optical area OA1 with respect to the boundary between the optical bezel area OBA1 and the optical area OA1.

The portion indicated by line X-Y in FIG. 7 may include the first light emitting area EA1 and the fourth light emitting area EA4 included in the optical area OA, and the second light emitting area EA2 included in the optical bezel area OBA. The first light emitting area EA1, the fourth light emitting area EA4, and the second light emitting area EA2 may represent light emitting areas EA emitting light of a same color.

FIG. 8 illustrates an example cross-sectional view of the display panel 110 according to aspects of the present disclosure, and more specifically, illustrates example cross-sectional views in the optical bezel area OBA and the optical area OA of the display panel 110. It should be noted here that FIG. 8 illustrates cross-sectional views based on the application of a 1:1 circuit connection scheme, as in FIG. 5.

Referring to FIG. 8, in terms of a stack up configuration, the display panel 110 may include a transistor forming part, a light emitting element forming part, and an encapsulation part.

The transistor forming part may include a substrate SUB, a first buffer layer BUF1 on the substrate SUB, various types of transistors DT1 and DT2 formed on the first buffer layer BUF, a storage capacitor Cst, and various electrodes and signal lines.

The substrate SUB may include, for example, a first substrate SUB1 and a second substrate SUB2, and may include an intermediate layer INTL interposed between the first substrate SUB1 and the second substrate SUB2. In this example, the intermediate layer INTL may be an inorganic layer and can serve to prevent moisture permeation.

A lower shield metal BSM may be disposed over the substrate SUB. The lower shield metal BSM may be located under a first active layer ACT1 of a first driving transistor DT1.

The first buffer layer BUF1 may include a stack of a single layer or a stack of a multilayer. In an example where the first buffer layer BUF1 includes a stack of a multilayer, the first buffer layer BUF1 may include a multi-buffer layer MBUF and an active buffer layer ABUF.

Various types of transistors (DT1, DT2, and the like), at least one storage capacitor Cst, and various electrodes or signal lines may be disposed on the first buffer layer BUF1.

For example, the transistors DT1 and DT2 formed on the first buffer layer BUF1 may include a same material, and be located in one or more same layers. In another example, as shown in FIG. 8, the first driving transistor DT1 and a second driving transistor DT2 among the transistors (DT1, DT2, and the like) may include different materials and be located in different layers.

Referring to FIG. 8, the first driving transistor DT1 may represent a driving transistor DT for driving the first light emitting element ED1 included in the optical area OA, and the second driving transistor DT2 may represent a driving transistor DT for driving the second light emitting element ED2 included in the optical bezel area OBA.

For example, the first driving transistor DT1 may represent a driving transistor included in the first pixel circuit SPC1 for driving the first light emitting element ED1 included in the optical area OA, and the second driving transistor DT2 may represent a driving transistor included in the second pixel circuit SPC2 for driving the second light emitting element ED2 included in the optical bezel area OBA.

Stackup configurations of the first driving transistor DT1 and the second driving transistor DT2 will be described below.

The first driving transistor DT1 may include the first active layer ACT1, a first gate electrode G1, a first source electrode S1, and a first drain electrode D1.

The second driving transistor DT2 may include a second active layer ACT2, a second gate electrode G2, a second source electrode S2, and a second drain electrode D2.

The second active layer ACT2 of the second driving transistor DT2 may be located in a higher location in the stackup configuration than the first active layer ACT1 of the first driving transistor DT1.

The first buffer layer BUF1 may be disposed under the first active layer ACT1 of the first driving transistor DT1, and the second buffer layer BUF2 may be disposed under the second active layer ACT2 of the second driving transistor DT2.

For example, the first active layer ACT1 of the first driving transistor DT1 may be located on the first buffer layer BUF1, and the second active layer ACT2 of the second driving transistor DT2 may be located on the second buffer layer BUF2. In this case, the second buffer layer BUF2 may be placed in a higher location than the first buffer layer BUF.

The first active layer ACT1 of the first driving transistor DT1 may be disposed on the first buffer layer BUF1, and a first gate insulating layer GI1 may be disposed on the first active layer ACT1 of the first driving transistor DT1. The first gate electrode G1 of the first driving transistor DT1 may be disposed on the first gate insulating layer GI1, and a first interlayer insulating layer ILD1 may be disposed on the first gate electrode G1 of the first driving transistor DT1.

In this implementation, the first active layer ACT1 of the first driving transistor DT1 may include a first channel region overlapping the first gate electrode G1, a first source connection region located on one side of the first channel region, and a first drain connection region located on the other side of the first channel region.

The second buffer layer BUF2 may be disposed on the first interlayer insulating layer ILD1.

The second active layer ACT2 of the second driving transistor DT2 may be disposed on the second buffer layer BUF2, and a second gate insulating layer GI2 may be disposed on the second active layer ACT2. The second gate electrode G2 of the second driving transistor DT2 may be disposed on the second gate insulating layer GI2, and a second interlayer insulating layer ILD2 may be disposed on the second gate electrode G2.

In this implementation, the second active layer ACT2 of the second driving transistor DT2 may include a second channel region overlapping the second gate electrode G2, a second source connection region located on one side of the second channel region, and a second drain connection region located on the other side of the second channel region.

The first source electrode S1 and the first drain electrode D1 of the first driving transistor DT1 may be disposed on the second interlayer insulating layer ILD2. The second source electrode S2 and the second drain electrode D2 of the second driving transistor DT2 may be also disposed on the second interlayer insulating layer ILD2.

The first source electrode S1 and the first drain electrode D1 of the first driving transistor DT1 may be respectively connected to the first source connection region and the first drain connection region of the first active layer ACT1 through through-holes formed in the second interlayer insulating layer ILD2, the second gate insulating layer GI2, the second buffer layer BUF2, the first interlayer insulating layer ILD1, and the first gate insulating layer GI1.

The second source electrode S2 and the second drain electrode D21 of the second driving transistor DT2 may be respectively connected to the second source connection region and the second drain connection region of the second active layer ACT2 through through-holes formed in the second interlayer insulating layer ILD2 and the second gate insulating layer GI2.

It should be understood that FIG. 8 illustrates only the second driving transistor DT2 and a storage capacitor Cst among circuit components included in the second pixel circuit SPC2, and other components such as one or more transistors, and the like are omitted. It should be also understood that FIG. 8 illustrates only the first driving transistor DT1 among circuit components included in the first pixel circuit SPC1, and other components such as one or more transistors, a storage capacitor, and the like are omitted.

Referring to FIG. 8, the storage capacitor Cst included in the second pixel circuit SPC2 may include a first capacitor electrode PLT1 and a second capacitor electrode PLT2.

The first capacitor electrode PLT1 may be electrically connected to the second gate electrode G2 of the second driving transistor DT2, and the second capacitor electrode PLT2 may be electrically connected to the second source electrode S2 of the second driving transistor DT2.

In one or more embodiments, referring to FIG. 8, a lower metal BML may be disposed under the second active layer ACT2 of the second driving transistor DT2. This lower metal BML may overlap all or at least a portion of the second active layer ACT2.

The lower metal BML may be electrically connected to, for example, the second gate electrode G2. In another example, the lower metal BML can serve as a light shield for shielding light traveling from a lower location than the lower metal BML. In this implementation, the lower metal BML may be electrically connected to the second source electrode S2.

Even though the first driving transistor DT1 is a transistor for driving the first light emitting element ED1 disposed in the optical area OA, the first driving transistor DT1 may be disposed in the optical bezel area OBA, not the optical area OA.

The second driving transistor DT2, which is a transistor for driving the second light emitting element ED2 disposed in the optical bezel area OBA, may be disposed in the optical bezel area OBA.

Referring to FIG. 8, the display panel 110 may include at least one planarization layer PLN disposed on the first driving transistor DT1 and the second driving transistor DT2.

Referring to FIG. 8, for example, the at least one planarization layer PLN may include a first planarization layer PLN1. For example, the first planarization layer PLN1 may be disposed on the first source electrode S1 and the first drain electrode D1 of the first driving transistor DT1 and the second source electrode S2 and the second drain electrode D2 of the second driving transistor DT2.

Referring to FIG. 8, a first relay electrode RE1 and a second relay electrode RE2 may be disposed on the first planarization layer PLN1.

The first relay electrode RE1 may represent an electrode for relaying an electrical interconnection between the first source electrode S1 of the first driving transistor DT1 and a first anode electrode AE1 of the first light emitting element ED1. The second relay electrode RE2 may represent an electrode for relaying an electrical interconnection between the second source electrode S2 of the second driving transistor DT2 and a second anode electrode AE2 of the second light emitting element ED2.

The first relay electrode RE1 may be electrically connected to the first source electrode S1 of the first driving transistor DT1 through a hole formed in the first planarization layer PLN1. The second relay electrode RE2 may be electrically connected to the second source electrode S2 of the second driving transistor DT2 through another hole formed in the first planarization layer PLN1.

Referring to FIG. 8, the first relay electrode RE2 and the second relay electrode RE2 may be disposed in the optical bezel area OBA.

Referring to FIG. 8, an anode extension line AEL may be connected to the first relay electrode RE1 and extend from the optical bezel area OBA to the optical area OA.

In one or more embodiments, referring to FIG. 8, the anode extension line AEL may be a metal layer disposed on the first relay electrode RE1 and include a transparent material.

Referring to FIG. 8, the at least one planarization layer PLN disposed on the display panel 110 may further include a second planarization layer PLN2 on the first planarization layer PLN1.

For example, the second planarization layer PLN2 may be disposed such that the second planarization layer PLN2 covers the first relay electrode RE1, the second relay electrode RE2, and the anode extension line AEL located on the first planarization layer PLN1.

Although FIG. 8 illustrates the example where the at least one planarization layer PLN includes the first planarization layer PLN1 and the second planarization layer PLN2, but embodiments of the present disclosure are not limited thereto. For example, the planarization layer PLN may further include at least one planarization layer PLN.

Referring to FIG. 8, the light emitting element forming part may be located on the second planarization layer PNL2.

Referring to FIG. 8, the light emitting element forming part may include the first light emitting element ED1, the second light emitting element ED2, and the fourth light emitting element ED4, which are disposed on the second planarization layer PNL2.

Referring to FIG. 8, the first light emitting element ED1 and the fourth light emitting element ED4 may be disposed in the optical area OA, and the second light emitting element ED2 may be disposed in the optical bezel area OBA.

In the example of FIG. 8, the first light emitting element ED1, the second light emitting element ED2, and the fourth light emitting element ED4 may be light emitting elements emitting light of a same color. Respective emission layers EL of the first light emitting element ED1, the second light emitting element ED2, and the fourth light emitting element ED4 may be formed independently of one another. However, in discussions that follow, for convenience of explanation, it is assumed that respective emission layers EL of the first light emitting element ED1, the second light emitting element ED2, and the fourth light emitting element ED4 are commonly formed as one common emission layer.

Referring to FIG. 8, the first light emitting element ED1 may be configured (i.e., made up) in an area where the first anode electrode AE1, the emission layer EL, and the cathode electrode CE overlap one another. The second light emitting element ED2 may be configured (i.e., made up) in an area where the second anode electrode AE2, the emission layer EL, and the cathode electrode CE overlap one another. The fourth light emitting element ED4 may be configured (i.e., made up) in an area where the fourth anode electrode AE4, the emission layer EL, and the cathode electrode CE overlap one another.

Referring to FIG. 8, the first anode electrode AE1, the second anode electrode AE2, and the fourth anode electrode AE4 may be disposed on the second planarization layer PLN2.

The second anode electrode AE2 may be connected to the second relay electrode RE2 through a hole formed in the second planarization layer PLN2.

The first anode electrode AE1 may be connected to an anode extension line AEL extending from the optical bezel area OBA to the optical area OA through another hole formed in the second planarization layer PLN2.

The fourth anode electrode AE4 may be connected to another anode extension line AEL extending from the optical bezel area OBA to the optical area OA through further another hole formed in the second planarization layer PLN2.

Referring to FIG. 8, a bank BK may be disposed on the first anode electrode AE1, the second anode electrode AE2, and the fourth anode electrode AE4.

The bank BK may include a plurality of bank holes, and respective portions of the first anode electrode AE1, the second anode electrode AE2, and the fourth anode electrode AE4 may be exposed through respective bank holes. That is, the plurality of bank holes formed in the bank BK may respectively overlap the respective portions of the first anode electrode AE1, the second anode electrode AE2, and the fourth anode electrode AE4.

Referring to FIG. 8, the emission layer EL may be disposed on the bank BK. The emission layer EL may contact the respective portions of the first anode electrode AE1, the second anode electrode AE2, and the fourth anode electrode AE4 through the plurality of bank holes.

Referring to FIG. 8, at least one spacer SPCR may be disposed between the emission layer EL and the bank BK.

Referring to FIG. 8, the cathode electrode CE may be disposed on the emission layer EL. The cathode electrode CE may include a plurality of cathode holes CH. The plurality of cathode holes CH formed in the cathode electrode CE may be disposed in the optical area OA.

One cathode hole CH illustrated in FIG. 8 may represent a cathode hole located between the first light emitting area EA1 and the fourth light emitting area EA4.

Referring to FIG. 8, the encapsulation part may be located on the cathode electrode CE. The encapsulation part may include an encapsulation layer ENCAP disposed on the cathode electrode CE.

Referring to FIG. 8, the encapsulation layer ENCAP can serve to prevent penetration of moisture or oxygen into the light emitting elements (ED1, ED2, and ED4) disposed under the encapsulation layer ENCAP. In particular, the encapsulation layer ENCAP may include an organic material or film and can serve to prevent penetration of moisture or oxygen into the emission layer EL. In one or more embodiments, the encapsulation layer ENCAP may include a stack of a single layer or a stack of a multilayer.

Referring to FIG. 8, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic material layers, and the second encapsulation layer PCL may be an organic material layer. Since the second encapsulation layer PCL is implemented using an organic material, the second encapsulation layer PCL can serve as a planarization layer.

In one or more embodiments, a touch sensor may be integrated into the display panel 110 according to aspects of the present disclosure. In these embodiments, the display panel 110 according to aspects of the present disclosure may include a touch sensor layer TSL disposed on the encapsulation layer ENCAP.

Referring to FIG. 8, the touch sensor layer TSL may include one or more touch sensor metals TSM and one or more bridge metals BRG, and may further include one or more insulating layers such as a sensor buffer layer S-BUF, a sensor interlayer insulating layer S-ILD, a sensor protective layer S-PAC, and the like. For example, the sensor interlayer insulating layer S-ILD may include one or more insulating layers.

The sensor buffer layer S-BUF may be disposed on the encapsulation layer ENCAP. The one or more bridge metals BRG may be disposed on the sensor buffer layer S-BUF, and the sensor interlayer insulating layer S-ILD may be disposed on the one or more bridge metals BRG.

The one or more touch sensor metals TSM may be disposed on the sensor interlayer insulating layer S-ILD. One or more of the touch sensor metals TSM may be connected to one or more respective bridge metals BRG among the bridge metals BRG through one or more respective holes formed in the sensor interlayer insulating layer S-ILD.

Referring to FIG. 8, the one or more touch sensor metals TSM and the one or more bridge metals BRG may be disposed in the optical bezel area OBA. The one or more touch sensor metals TSM and the one or more bridge metals BRG may be disposed not to overlap the second light emitting area EA2 of the optical bezel area OBA.

A plurality of touch sensor metals TSM may be configured as one touch electrode (or one touch electrode line). For example, the plurality of touch sensor metals TSM may be arranged in a mesh pattern and therefore electrically connected to one another. One or more of the touch sensor metals TSM and the remaining one or more touch sensor metals TSM may be electrically connected through one or more respective bridge metals BRG, and thereby, be configured as one touch electrode (or one touch electrode line).

The sensor protective layer S-PAC may be disposed such that it covers the one or more touch sensor metals TSM and the one or more bridge metals BRG.

In an embodiment where a touch sensor is integrated into the display panel 110, at least one of the touch sensor metals TSM, or at least a portion of at least one of the touch sensor metals TSM, located on the encapsulation layer ENCAP may extend along an inclined surface formed in an edge of the encapsulation layer ENCAP, and be electrically connected to a pad located in an edge of the display panel 110 that is further away from the inclined surface of the edge of the encapsulation layer ENCAP. The pad may be disposed in the non-display area NDA and may be a metal pattern to which the touch driving circuit 260 is electrically connected.

The display panel 110 according to aspects of the present disclosure may include the bank BK disposed on the first anode electrode AE1 and having a bank hole exposing a portion of the first anode electrode AE1, and the emission layer EL disposed on the bank BK and contacting the portion of the first anode electrode AE1 exposed through the bank hole.

The bank hole formed in the bank BK may not overlap a plurality of cathode holes CH. For example, the bank BK may not be depressed or perforated (i.e., remained in a flat state) at places where the plurality of cathode holes CH are present. Thus, at places where the plurality of cathode holes CH are present, the second planarization layer PLN and the first planarization layer PLN1 located under the bank BK may not be depressed or perforated as well (i.e., remained in a flat state).

The flat state of the respective portion of the upper surface of the bank BK located under any one of the plurality of cathode holes CH may mean that one or more insulating layers or one or more metal patterns (e.g., one or more electrode, one or more lines, and/or the like), or the emission layers EL located under any one of the plurality of cathode holes CH have not been damaged by the process of forming the plurality of cathode holes CH in the cathode electrode CE.

A brief description for the process of forming cathode holes CH in the cathode electrode CE is as follows. A specific mask pattern can be deposited at respective locations where the cathode holes CH are to be formed, and then, a cathode electrode material can be deposited thereon. Accordingly, the cathode electrode material can be deposited only in an area where the specific mask pattern is not located, and thereby, the cathode electrode CE including the cathode holes CH can be formed. The specific mask pattern may include, for example, an organic material. The cathode electrode material may include a magnesium-silver (Mg—Ag) alloy.

In one or more embodiments, after the cathode electrode CE having the cathode holes CH is formed, the display panel 110 may be in a situation in which the specific mask pattern is completely removed, partially removed (where a portion of the specific mask pattern remains), or not removed (where all of the specific mask pattern remains without being removed).

In one or more embodiments, the display panel 110 according to aspects of the present disclosure may include the first driving transistor DT1 disposed in the optical bezel area OBA to drive the first light emitting element ED1 disposed in the optical area OA, and the second driving transistor DT2 disposed in the optical bezel area OBA to drive the second light emitting element ED2 disposed in the optical bezel area OBA.

In one or more embodiments, the display panel 110 according to aspects of the present disclosure may further include the first planarization layer PLN1 disposed on the first driving transistor DT1 and the second driving transistor DT2, the first relay electrode RE1 disposed on the first planarization layer PLN1 and electrically connected to the first source electrode S1 of the first driving transistor DT1 through a hole formed in the first planarization layer PLN1, the second relay electrode RE2 disposed on the first planarization layer PLN1 and electrically connected to the second source electrode S2 of the second driving transistor DT2 through another hole formed in the first planarization layer PLN1, and the second planarization layer PLN2 disposed on the first relay electrode RE1 and the second relay electrode RE2.

In one or more embodiments, the display panel 110 according to aspects of the present disclosure may further include an anode extension line (e.g., the anode extension line AEL) interconnecting the first relay electrode RE1 and the first anode electrode AE1, and located on the first planarization layer PLN1.

The second anode electrode AE2 may be electrically connected to the second relay electrode RE2 through a hole formed in the second planarization layer PLN2, and the first anode electrode AE1 may be electrically connected to the anode extension line AEL through another hole formed in the second planarization layer PLN2.

All or at least a portion of the anode extension line AEL may be disposed in the optical area OA, and the anode extension line AEL may include a transparent material, or be or include a transparent line.

The first pixel circuit SPC1 may include the first driving transistor DT1 for driving the first light emitting element ED1, and the second pixel circuit SPC2 may include the second driving transistor DT2 for driving the second light emitting element ED2.

The first active layer ACT1 of the first driving transistor DT1 may be located in a different layer from the second active layer ACT2 of the second driving transistor DT2.

In one or more embodiments, the display panel 110 according to aspects of the present disclosure may further include the substrate SUB, the first buffer layer BUF1 disposed between the substrate SUB and the first driving transistor DT1, and the second buffer layer BUF2 disposed between the first driving transistor DT1 and the second driving transistors DT2.

The first active layer ACT1 of the first driving transistor DT1 may include a different semiconductor material from the second active layer ACT2 of the second driving transistor DT2.

For example, the second active layer ACT2 of the second driving transistor DT2 may include an oxide semiconductor material. For example, such an oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like.

For example, the first active layer ACT1 of the first driving transistor DT1 may include a different semiconductor material from the second active layer ACT2 of the second driving transistor DT2.

For example, the first active layer ACT1 of the first driving transistor DT1 may include a silicon-based semiconductor material. For example, the silicon-based semiconductor material may include low-temperature polycrystalline silicon (LTPS) or the like.

In one or more embodiments, the display panel 110 according to aspects of the present disclosure may further include the encapsulation layer ENCAP located on the first light emitting element ED1, the second light emitting element ED2, and the third light emitting element ED3, and touch sensor metals TSM located on the encapsulation layer ENCAP.

The touch sensor metals TSM may be disposed in the normal area NA and the optical bezel area OBA. For example, the touch sensor metals TSM may not be disposed in the optical area OA. In another example, the touch sensor metals TSM may be disposed in the optical area OA, the normal area NA and the optical bezel area OBA such that the optical area OA has a lower touch sensor metal density than each of the normal area NA and the optical bezel area OBA.

Referring to FIG. 8, the optical area OA may overlap an optical electronic device. The optical bezel area OBA may not overlap an optical electronic device. One or more embodiments, a portion of the optical bezel area OBA may overlap an optical electronic device.

The optical electronic device overlapping the optical area OA may be the first optical electronic device 11 and/or the second optical electronic device 12 in FIGS. 1A, 1B and 1C discussed above. For example, the optical electronic device may include a camera, an infrared sensor, an ultraviolet sensor, and/or the like. For example, the optical electronic device may be a device capable of receiving visible light and performing a predetermined operation, or a device capable of receiving light (e.g., infrared light, and/or ultraviolet light) different from visible light and performing a predetermined operation.

Referring to FIG. 8, a cross-sectional structure of the normal area NA may be substantially or nearly the same as that of the optical bezel area OBA. It should be noted here that the first pixel circuit SPC1 disposed in the optical bezel area OBA to drive the first light emitting element ED1 disposed in the optical area OA may not be disposed in the normal area NA.

FIG. 9 illustrates an example cross-sectional view of the display panel 110 according to aspects of the present disclosure, and more specifically, illustrates example cross-sectional views in the optical bezel area OBA and the optical area OA of the display panel 110. It should be noted here that FIG. 9 illustrates an example cross-sectional view based on the application of a 1:2 circuit connection scheme, as in FIG. 6.

The cross-sectional view of FIG. 9 is basically the same as the cross-sectional view of FIG. 8. It should be noted here that one difference between the cross-sectional views of FIGS. 8 and 9 is that while FIG. 8 employs the 1:1 circuit connection scheme as in FIG. 5, FIG. 9 employs the 1:2 circuit connection scheme as in FIG. 6. Taking account of the similarity between them, hereinafter, descriptions on the cross-sectional structure of FIG. 9 will be provided by focusing on features different from the cross-sectional structure of FIG. 8.

Referring to FIG. 9, the first light emitting element ED1 and the fourth light emitting element ED4 disposed in the optical area OA may be driven the first driving transistor DT1 disposed in the optical bezel area OBA together or substantially concurrently.

Accordingly, as illustrated in FIG. 9, an anode extension line AEL (e.g., the anode extension line AEL of FIG. 8) may be further electrically connected to the fourth anode electrode AE4 different from the first anode electrode AE1, as well as the first anode electrode AE1. Thus, the anode extension line AEL may be electrically connected to both the first anode electrode AE1 of the first light emitting element ED1 and the fourth anode electrode AE4 of the fourth light emitting element ED4.

Referring to FIG. 9, the anode extension line AEL may overlap a cathode hole CH located between the first light emitting element ED1 and the fourth light emitting element ED4 among a plurality of cathode holes CH.

Referring to FIG. 9, the first light emitting area EA1 configured by the first light emitting element ED1 and the fourth light emitting area EA4 configured by the fourth light emitting element ED4 may be light emitting areas emitting light of a same color.

For example, in the optical area OA, an area except for a plurality of cathode holes CH, which are transmissive areas TA, may be an area through which light cannot be transmitted. In another example, in the optical area OA, the area except for the plurality of cathode holes CH, which are transmissive areas TA, may be an area through which light can be transmitted with a low transmittance (or a low transmissivity).

Thus, in the optical area OA, the transmittance (or transmissivity) of the area except for the plurality of cathode holes CH may be lower than that of the plurality of cathode holes CH. In one or more embodiments, the transmittance (or transmissivity) of the area except for the plurality of cathode holes CH in the optical area OA may be higher than that of the normal area NA.

FIG. 10 schematically illustrates an example second type of optical area OA and an example normal area NA around the second type of optical area OA in the display panel 110 according to aspects of the present disclosure.

Referring to FIG. 10, the display area DA may include an optical area OA. The optical area OA may have the structure of a second type. In the example where the optical area OA is implemented in the second type, the optical area OA may include a plurality of transmissive areas TA and a low-transmissive area LTA. The second type may be also referred to as a hole type.

Referring to FIG. 10, in the optical area OA, the low-transmissive area LTA except for the plurality of transmissive areas TA may include a plurality of light emitting areas EA. In the optical area OA, a plurality of light emitting elements ED for the plurality of light emitting areas EA may be disposed in the low-transmissive area LTA except for the plurality of transmissive areas TA.

Further, a plurality of pixel circuits SPC for driving the plurality of light emitting elements ED may be disposed in the low-transmittable area LTA. That is, the plurality of pixel circuits SPC may be disposed in the optical area OA. This is different from the first type (i.e., the anode extension type) of the optical area OA in the examples of FIGS. 4 to 9 in which that the plurality of pixel circuits SPC are not disposed in the optical area OA.

In one embodiment, the low-transmissive area LTA in the optical area OA may be an area through which light cannot be transmitted. In another embodiment, the low-transmissive area LTA in the optical area OA may be an area through which light can be transmitted with a low transmittance (or a low transmissivity).

In the optical area OA, the transmittance (or transmissivity) of the low-transmissive area LTA may be lower than that of the transmissive area TA. In one or more embodiments, the transmittance (or transmissivity) of the low-transmissive area LTA in the optical area OA may be higher than that of the normal area NA.

Referring to FIG. 10, the arrangement of light emitting areas EA in the optical area OA may be the same as the arrangement of light emitting areas EA in the normal area NA.

One or more embodiments, referring to FIG. 10, a respective area of each of a plurality of light emitting areas EA included in the optical area OA may be the same or substantially or nearly the same as, or be different within a predetermined range from, a respective area of each of a plurality of light emitting areas EA included in the normal area NA.

Further, a respective area of each of the plurality of light emitting areas EA included in the optical area OA may be the same or substantially or nearly the same as, or be different within a predetermined range.

A cathode electrode (e.g., the cathode electrode CE in FIG. 3) may be commonly disposed in the normal area NA and the optical area OA, and may include a plurality of cathode holes CH in the optical area OA. The plurality of cathode holes CH of the cathode electrode CE may respectively correspond to the transmissive areas TA of the optical area OA.

Since the optical area OA includes the plurality of transmissive areas TA, the optical area OA may have higher transmittance than the normal area NA.

All or at least a portion of the optical area OA may overlap an optical electronic device.

The optical electronic device overlapping the optical area OA may be the first optical electronic device 11 and/or the second optical electronic device 12 in FIGS. 1A, 1B and 1C discussed above. For example, the optical electronic device may include a camera, an infrared sensor, an ultraviolet sensor, and/or the like. For example, the optical electronic device may be a device capable of receiving visible light and performing a predetermined operation, or a device capable of receiving light (e.g., infrared light, and/or ultraviolet light) different from visible light and performing a predetermined operation.

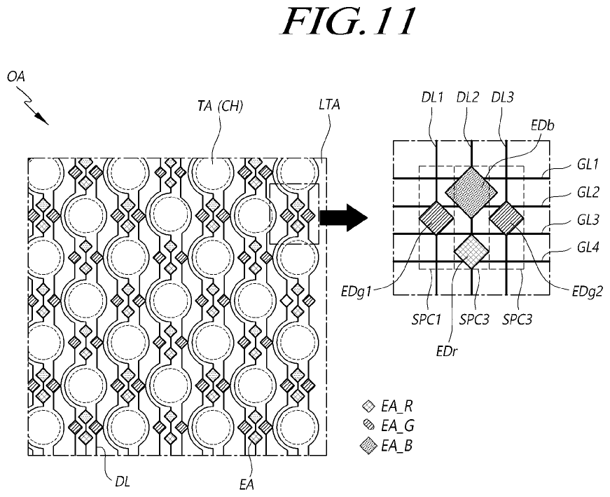

FIG. 11 is an example plan view of the second type of optical area OA (e.g., as in the configuration of the FIG. 10) in the display panel 110 according to embodiments of the present disclosure.

Referring to FIG. 11, in an example where the optical area OA is implemented in the second type, the optical area OA may include one or more transmissive areas TA and a low-transmissive area LTA except for the one or more transmissive areas.

The low-transmissive area LTA may include a plurality of light emitting areas EA.

A respective light emitting element ED may be disposed in each of the plurality of light emitting areas EA.

A plurality of pixel circuits SPC for driving the plurality of light emitting elements ED may be disposed in the low-transmissive area LTA.

In the second type of optical area OA, the light emitting elements ED and the pixel circuits SPC may partially overlap each other.

In the case of the second type of optical area OA, data lines (DL1, DL2 and DL3) and gate lines (GL1, GL2, GL3, and GL4) may extend across the optical area OA.

In the optical area OA, the data lines (DL1, DL2 and DL3) may be arranged in a column direction (or a row direction) while avoiding one or more transmissive areas TA, which correspond to one or more respective cathode holes CH.

In the optical area OA, the gate lines (GL1, GL2, GL3, and GL4) may be arranged in the row direction (or the column direction) while avoiding one or more transmissive areas TA, which correspond to one or more respective cathode holes CH.

The data lines (DL1, DL2 and DL3) and the gate lines (GL1, GL2, GL3, and GL4) may be connected to pixel circuits (SPC1, SPC2, and SPC3) disposed in the optical area OA.

For example, four light emitting elements (EDr, EDg1, EDg2, and EDb) may be disposed in a portion of the low-transmissive area LTA between four adjacent transmissive areas TA. The four light emitting elements (EDr, EDg1, EDg2, and EDb) may include one red light emitting element EDr, two green light emitting elements EDg1 and EDg2, and one blue light emitting element EDb.

For example, a pixel circuit SPC1 for driving the one red light emitting element EDR may be connected to a first data line DL1 and a first gate line GL1. A pixel circuit SPC2 for driving the two green light emitting elements EDg1 and EDg2 may be connected to a second data line DL2, a second gate line GL2, and a third gate line GL3. A pixel circuit SPC3 for driving the one blue light emitting element EDb may be connected to a third data line DL3 and a fourth gate line GL4.

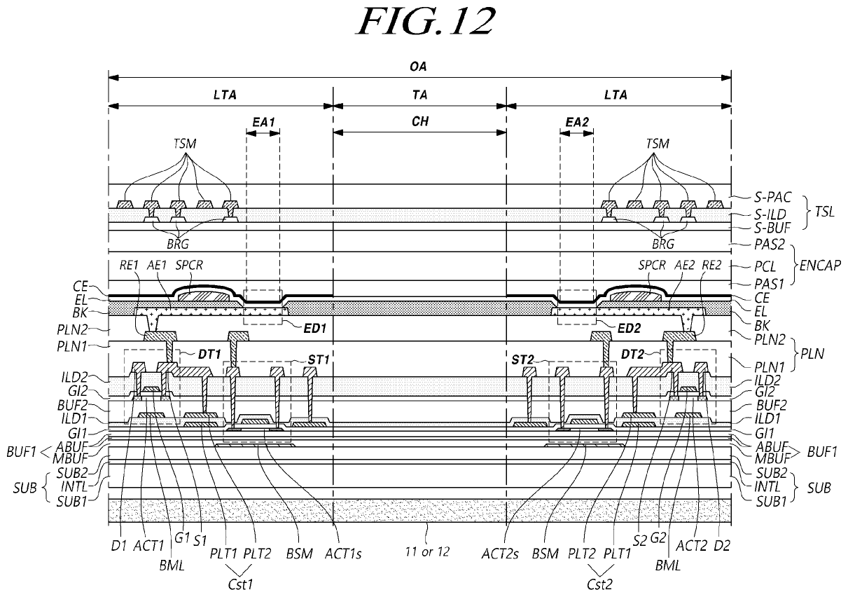

FIG. 12 is an example cross-sectional view of the second type of optical area OA (e.g., as in the configuration of FIGS. 10 and 11) in the display panel 110 according to aspects of the present disclosure.

Metal layers and insulating layers in the cross-sectional structure of FIG. 12 may be the same, or substantially or nearly the same, as the metal layers and insulating layers in the cross-sectional structures of FIGS. 8 and 9. Taking account of the similarity between them, discussions on the cross-sectional structure of FIG. 12 will be provided by focusing on features different from those of the cross-sectional structures of FIGS. 8 and 9.

Referring to FIG. 12, an optical electronic device may be disposed such that it overlaps all or at least a portion of the optical area OA. The optical electronic device may be the first optical electronic device 11 and/or the second optical electronic device 12 in FIGS. 1A, 1B and 1C discussed above.

Referring to FIG. 12, a first light emitting element ED1 and a second light emitting element ED2 may be disposed in the optical area OA. A first light emitting area EA1 configured by the first light emitting element ED1 and a second light emitting area EA2 configured by the second light emitting element ED2 may be light emitting areas emitting light of a same color.

Referring to FIG. 12, an area where the first light emitting element ED1 and the second light emitting element ED2 are disposed may be a low-transmissive area LTA, and a transmissive area TA may be located between the first light emitting element ED1 and the second light emitting element ED2. That is, the transmissive area TA may be located between the first light emitting area EA1 configured by the first light emitting element ED1 and the second light emitting area EA2 configured by the second light emitting element ED2.

A pixel circuit SPC can be configured to drive the first light emitting element ED1, and may be disposed to overlap all or at least a portion of the first light emitting element ED1 in the optical area OA.

Referring to FIG. 12, the pixel circuit SPC for driving the first light emitting element ED1 may include a first driving transistor DT1, a first scan transistor ST1, and a first storage capacitor Cst1.

A pixel circuit SPC can be configured to drive the second light emitting element ED2, and may be disposed to overlap all or at least a portion of the second light emitting element ED2 in the optical area OA.

Referring to FIG. 12, the pixel circuit SPC for driving the second light emitting element ED2 may include a second driving transistor DT2, a second scan transistor ST2, and a second storage capacitor Cst2.

Referring to FIG. 12, the first driving transistor DT1 may include a first active layer ACT1, a first gate electrode G1, a first source electrode S1, and a first drain electrode D1.

The first light emitting element ED1 may be configured (i.e., made up) in an area where a first anode electrode AE1, an emission layer EL, and a cathode electrode CE overlap one another.

The first source electrode S1 of the first driving transistor DT1 may be connected to the first anode electrode AE1 through a first relay electrode RE1.

The first storage capacitor Cst1 may include a first capacitor electrode PLT1 and a second capacitor electrode PLT2.

The first source electrode S1 of the first driving transistor DT1 may be connected to the second capacitor electrode PLT2 of the first storage capacitor Cst1.

The first gate electrode G1 of the first driving transistor DT1 may be connected to the first capacitor electrode PLT1 of the first storage capacitor Cst1.

The active layer ACT1s of the first scan transistor ST1 may be located on the first buffer layer BUF1 and be located in a lower location than the first active layer ACT1 of the first driving transistor DT1.

A semiconductor material included in the active layer ACT1s of the first scan transistor ST1 may be different from a semiconductor material included in the first active layer ACT1 of the first driving transistor DT1. For example, the semiconductor material included in the first active layer ACT1 of the first driving transistor DT1 may be an oxide semiconductor material, and the semiconductor material included in the active layer ACT1s of the first scan transistor ST1 may be a silicon-based semiconductor material (e.g., a low-temperature polycrystalline silicon (LTPS)).

Referring to FIG. 12, the second driving transistor DT2 may include a second active layer ACT2, a second gate electrode G2, a second source electrode S2, and a second drain electrode D2.

The second light emitting element ED2 may be configured (i.e., made up) in an area where a second anode electrode AE2, the emission layer EL, and the cathode electrode CE overlap one another.

The second source electrode S2 of the second driving transistor DT2 may be connected to the second anode electrode AE2 through a second relay electrode RE2.

The second storage capacitor Cst2 may include a first capacitor electrode PLT1 and a second capacitor electrode PLT2.

The second source electrode S2 of the second driving transistor DT1 may be connected to the second capacitor electrode PLT2 of the second storage capacitor Cst2.

The second gate electrode G2 of the second driving transistor DT2 may be connected to the first capacitor electrode PLT1 of the second storage capacitor Cst2.

An active layer ACT2s of the second scan transistor ST2 may be located on the first buffer layer BUF1 and be located in a lower location than the second active layer ACT2 of the second driving transistor DT2.

A semiconductor material included in the active layer ACT2s of the second scan transistor ST2 may be different from a semiconductor material included in the second active layer ACT2 of the second driving transistor DT2. For example, the semiconductor material included in the second active layer ACT2 of the second driving transistor DT2 may be an oxide semiconductor material, and the semiconductor material included in the active layer ACT2s of the second scan transistor ST2 may be a silicon-based semiconductor material (e.g., a low-temperature polycrystalline silicon (LTPS)).

The cathode electrode CE may not include a cathode hole CH or may include a plurality of cathode holes CH.

In an example where the cathode electrode CE includes a plurality of cathode holes CH, the cathode holes CH formed in the cathode electrode CE may be located to correspond to respective transmissive areas TA of the optical area OA.

A bank hole formed in the bank BK may not overlap any one of the cathode holes CH.

An upper surface of the bank BK located in a lower location than the cathode holes CH may be flat without being depressed or etched. For example, the bank BK may not be depressed or perforated (i.e., remained in the flat state) at places where cathode holes CH are present. Thus, at places where cathode holes CH are present, the second planarization layer PLN2 and the first planarization layer PLN1 located in a lower location than the bank BK may not be depressed or perforated as well (i.e., remained in a flat state).

The flat state of the respective portions of the upper surface of the bank BK located under the cathode holes CH may mean that one or more insulating layers or one or more metal patterns (e.g., one or more electrode, one or more lines, and/or the like), or the emission layer EL located under the cathode electrode CE have not been damaged by the process of forming the cathode holes CH in the cathode electrode CE.

A brief description for the process of forming cathode holes CH in the cathode electrode CE is as follows. A specific mask pattern can be deposited at respective locations where the cathode holes CH are to be formed, and then, a cathode electrode material can be deposited thereon. Accordingly, the cathode electrode material can be deposited only in an area where the specific mask pattern is not located, and thereby, the cathode electrode CE including the cathode holes CH can be formed.

The specific mask pattern may include, for example, an organic material. The cathode electrode material may include a magnesium-silver (Mg—Ag) alloy.

In one or more embodiments, after the cathode electrode CE having the cathode holes CH is formed, the display panel 110 may be in a situation in which the specific mask pattern is completely removed, partially removed (where a portion of the specific mask pattern remains), or not removed (where all of the specific mask pattern remains without being removed).

As discussed above, while transistors (e.g., DT and/or ST) and a storage capacitor Cst may not be disposed in the optical area OA configured in the first type (i.e., the anode extension type) as in the examples of FIGS. 4 to 9, transistors (e.g., DT and/or ST) and one or more storage capacitors Cst may be disposed in the optical area OA configured in the second type (i.e., the hole type) as in the examples of FIGS. 10 to 12.

In the first type (i.e., the anode extension type) of FIGS. 4 to 9, two or more light emitting elements ED may be disposed in the optical area OA, and two or more light emitting elements ED may be also disposed in the optical bezel area OBA, which is an area located outside of the optical area OA. Further, in the first type (i.e., the anode extension type), transistors (e.g., DT and/or ST) and a storage capacitor Cst may not be disposed in the optical area OA, and transistors (e.g., DT and/or ST) and one or more storage capacitors Cst may be disposed in the optical bezel area OBA located outside of the optical area OA.

Referring to FIG. 10 to 12, in the second type (i.e., the hole type), two or more light emitting elements ED may be disposed in the optical area OA. That is, in the optical area OA of the second type (i.e., the hole type), two or more light emitting elements ED may be disposed in the low-transmissive area LTA of the optical area OA. Further, in the second type (i.e., the hole type), transistors (e.g., DT and/or ST) and one or more storage capacitors Cst may be disposed in the optical area OA. That is, in the optical area OA of the second type (i.e., the hole type), transistors (e.g., DT and/or ST) and one or more storage capacitors Cst may be disposed in the low-transmissive area LTA of the optical area OA.

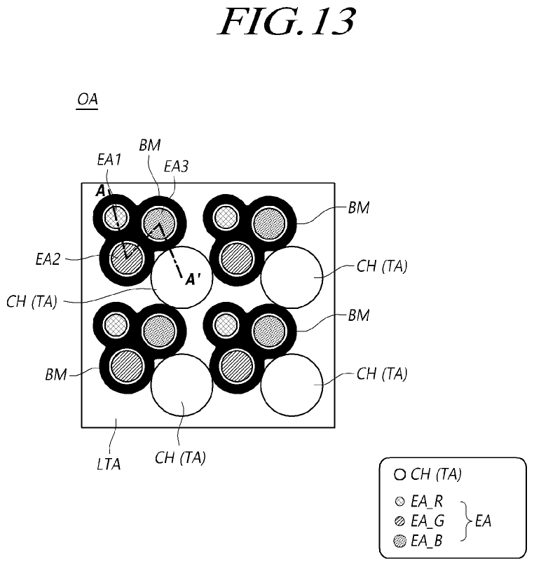

Hereinafter, structures of the optical area OA in the display panel 110 according to aspects of the present disclosure will be described in more detail with reference to FIGS. 13 to 16.

FIG. 13 is a plan view illustrating an example structure capable of improving display performance in the optical area of the display panel according to embodiments of the present disclosure.

Referring to FIG. 13, in one or more embodiments, in the display panel 110 according to embodiments of the present disclosure, the optical area OA may include a plurality of transmissive areas TA and a low-transmissive area LTA different from the plurality of transmissive areas TA.

Each of the plurality of transmissive areas TA may represent a respective cathode hole CH. A light emitting area EA may not be disposed in the plurality of transmissive areas TA.

Referring to FIG. 13, the low-transmissive area LTA may include a plurality of light emitting areas EA. Accordingly, a plurality of light emitting elements ED forming the plurality of light emitting areas EA may be disposed in the low-transmissive area LTA.

As described above, the low-transmissive area LTA may be an area through which light cannot be transmitted or an area through which light can be transmitted at lower transmittance than the plurality of transmissive areas TA.

The optical area OA of FIG. 13 may be implemented in the first type (i.e., the anode extension type) or the second type (i.e., the hole type).

In the example where the optical area OA of FIG. 13 is implemented in the first type, pixel circuits SPC for driving light emitting elements ED may not be disposed in the low-transmissive area LTA of the optical area OA, but may be disposed in an optical bezel area OBA surrounding the optical area OA.

In the example where the optical area OA of FIG. 13 is implemented in the second type, pixel circuits SPC for driving light emitting elements ED may be disposed in the low-transmissive area LTA of the optical area OA.

Referring to FIG. 13, the display panel 110 may include a black matrix BM serving as a boundary between light emitting areas EA included in the low-transmissive area LTA of the optical area OA.

Referring to FIG. 13, the black matrix BM in the optical area OA may have a black band shape surrounding light emitting areas EA included in the low-transmissive area LTA of the optical area OA.

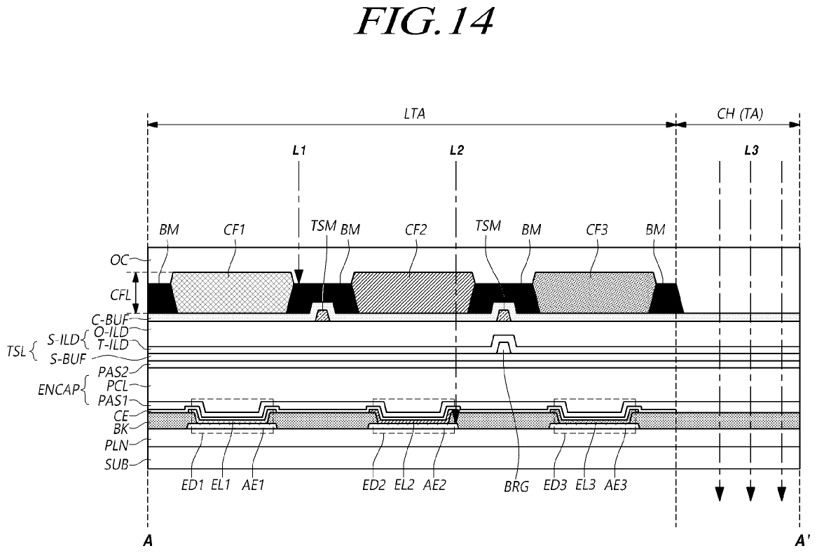

Referring to FIG. 13, the black matrix BM can serve as a partition separating respective areas of subpixels before color filters (CF1, CF2, and CF3 of FIG. 14) are formed, distinguish respective light emitting areas EA of the subpixels SP from one another, and prevent color mixing of the subpixels SP.

Referring to FIG. 13, a first light emitting area EA1, a second light emitting area EA2, a third light emitting area EA3, and a transmissive area TA may be disposed along line A-A′. For example, the first light emitting area EA1 may be a red light emitting area EA_R, the second light emitting area EA2 may be a green light emitting area EA_G, and the third light emitting area EA3 may be a blue light emitting area EA_B.

Hereinafter, a vertical structure (e.g., a stackup configuration) taken along line A-A′ of FIG. 13 will be described through a cross-sectional view of FIG. 14.

FIG. 14 is an example cross-sectional view taken along line A-A′ of FIG. 13 according to one embodiment.

It should be noted here that the stackup configuration of FIG. 14 except for a color filter layer CFL may be the same, or substantially or nearly the same, as the stackup configuration of FIG. 8, 9, or 12. For simplicity, it should be also noted that the cross-sectional view of FIG. 14 includes a configuration resulting from simplifying the stackup configuration of FIG. 8, 9, or 12.

Referring to FIG. 14, in the optical area OA, a planarization layer PLN may be disposed on a substrate SUB. For example, the planarization layer PLN may include a stack of a single layer or a stack of a multilayer.

In the optical area OA, anode electrodes (AE1, AE2, and AE3) may be disposed on the planarization layer PLN.

A bank BK may be disposed on the anode electrodes (AE1, AE2, and AE3), and include openings respectively exposing respective portions of the anode electrodes (AE1, AE2, and AE3) for enabling light emitting areas (EA1, EA2, and EA3) to be formed.

Emission layers (EL1, EL2, and EL3) may be disposed on the respective portions of the anode electrodes (AE1, AE2, and AE3) exposed by the openings of the bank BK. Each of the emission layers (EL1, EL2, and EL3) may extend around the respective opening of the bank BK, and may be disposed in one or more side surfaces of the respective opening of the bank BK and/or one or more portions of an upper surface of the bank BK.

A cathode electrode CE may be disposed such that it covers the emission layers (EL1, EL2, and EL3).

Referring to FIG. 14, a first light emitting element ED1 may be configured with a first anode electrode AE1, a first emission layer EL1, and the cathode electrode CE, and a first light emitting area EA1 can be formed by the driving of the first light emitting element ED1.

A second light emitting element ED2 may be configured with a second anode electrode AE2, a second emission layer EL2, and the cathode electrode CE, and a second light emitting area EA2 can be formed by the driving of the second light emitting element ED2.

A third light emitting element ED3 may be configured with a third anode electrode AE3, a third emission layer EL3, and the cathode electrode CE, and a third light emitting area EA3 can be formed by the driving of the third light emitting element ED3.

Referring to FIG. 14, the cathode electrode CE may be disposed in the low-transmissive area LTA and may not be disposed in the transmissive area TA. For example, in the transmissive area TA, the cathode electrode CE may have cathode holes CH.

Referring to FIG. 14, an encapsulation layer ENCAP may be disposed on the cathode electrode CE. The encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer.

Referring to FIG. 14, a touch sensor layer TSL may be disposed on the encapsulation layer ENCAP. The touch sensor layer TSL may include a sensor buffer layer S-BUF on the encapsulation layer ENCAP, one or more bridge metals BRG on the sensor buffer layer S-BUF, a sensor interlayer insulating layer S-ILD disposed on the one or more bridge metals BRG such that the sensor interlayer insulating layer S-ILD covers the one or more bridge metals BRG, and one or more touch sensor metals TSM on the sensor interlayer insulating layer S-ILD.

The sensor interlayer insulating layer S-ILD may include a touch interlayer insulating layer T-ILD and an organic interlayer insulating layer O-ILD. For example, the touch interlayer insulating layer T-ILD may be an inorganic layer, and the organic interlayer insulating layer O-ILD may be an organic layer.

Referring to FIG. 14, in one or more embodiments, the display device 100 according to aspects of the present disclosure may have a structure in which a color filter layer CFL is disposed on the encapsulation layer ENCAP. For this implementation, the display panel 110 may include a color filter buffer layer C-BUF and a color filter layer CFL, which are disposed on the touch sensor layer TSL. Hereinafter, for convenience of description, a structure in which the color filter layer CFL is disposed on the encapsulation layer ENCAP is also referred to as a color filter on encapsulation layer (COE) structure.

The color filter layer CFL may be disposed in the low-transmissive area LTA and may not be disposed in the transmissive area TA. The color filter layer CFL may include color filters (CF1, CF2, and CF3) and a black matrix BM located in a boundary area between the color filters (CF1, CF2, and CF3).

Referring to FIG. 14, in the low-transmissive area LTA of the optical area OA, first light L1 incident to the front surface can be shielded by the black matrix BM, and second light L2 incident by passing through the color filter CF2 can shielded by the anode electrode AE2.

Referring to FIG. 14, in the transmissive area TA of the optical area OA, third light L3 incident to the front surface can be transmitted and exit from the rear surface of the substrate SUB.

Referring to FIG. 14, the area of the light emitting area EA may be reduced by the black matrix BM.

As described above, the black matrix BM can serve as a boundary between light emitting areas EA included in the low-transmissive area LTA of the optical area OA, serve as a partition separating respective areas of subpixels, distinguish the light emitting areas EA of the subpixels SP from one another, and prevent color mixing of the subpixels SP. Accordingly, corresponding contrast ratio can be improved, and thereby, display performance can be improved.

Meanwhile, as in the display device 100 according to aspects of the present disclosure, in examples where one or more optical electronic devices (11 and/or 12) are disposed under the display area DA of the display panel 110, it is desired to increase the transmittance of the optical area OA in order to improve operation performance (particularly, camera performance) of the one or more optical electronic devices (11 and/or 12). The transmittance of the optical area OA can produce a significant effect on the operation performance of the one or more optical electronic devices (11 and/or 12).

Since the display device 100 according to aspects of the present disclosure has the COE structure in which the color filter layer CFL is disposed on the encapsulation layer ENCAP, an effect of improving transmittance can be obtained; however, an open area (or an open ratio) of the display panel 110 may be reduced by the black matrix BM included in the color filter layer CFL. Such a reduction in the opening area of the display panel 110 can limit an increase in transmittance of the optical area OA.

In other words, since the display device 100 has the COE structure, although the transmittance of the optical area OA can be increased, the increase of the transmittance of the optical area OA can be limited due to the decrease in the open area by the black matrix BM.

In particular, in an example where a transparent line such as an anode extension line AEL is disposed in the optical area OA, the decrease in the open area due to the black matrix BM may act as a factor reducing the transmittance improvement effect of such a transparent line.

Therefore, in examples where one or more transparent lines and the COE (color filter on encapsulation layer) structure are applied, it may be desired to expand an open area (or an open ratio) in order to maximize the transmittance of the optical area OA.

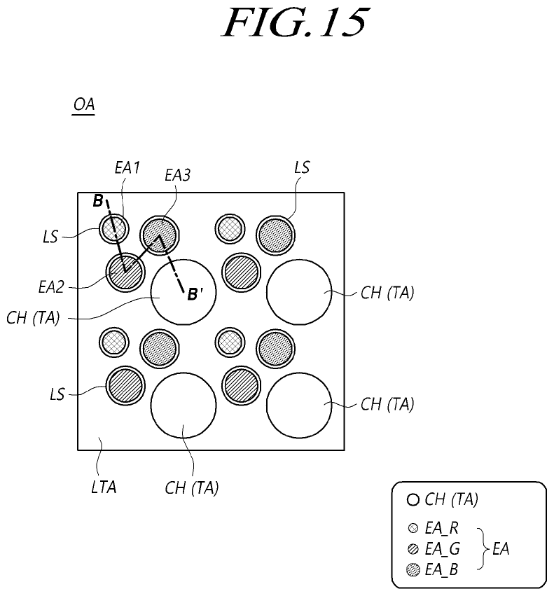

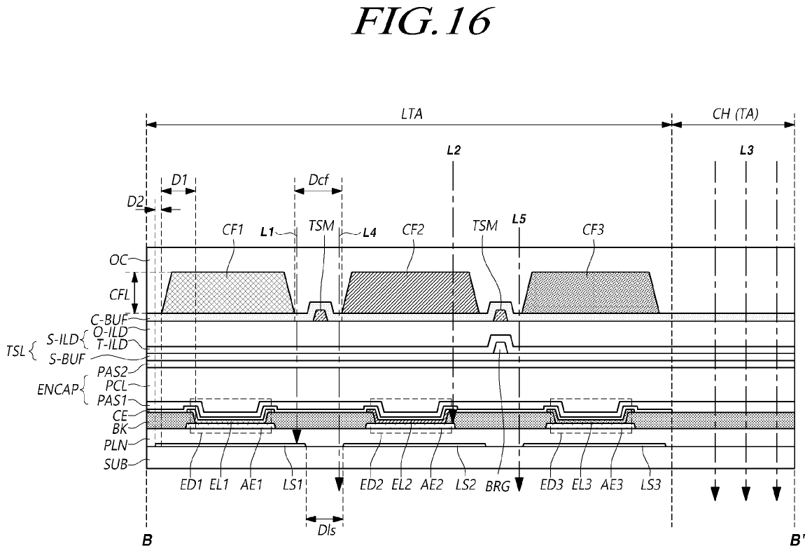

To meet this requirement, in one or more embodiments, in the display device 100 according to aspects of the present disclosure, the optical area OA may have, as a structure for expanding an open area and improving transmittance, a structure in which the black matrix BM is removed and a structure in which external light is shielded. Hereinafter, a structure for expanding an opening area and improving transmittance employed in the optical area OA of the display device 100 according to aspects of the present disclosure will be described in more detail with reference to FIGS. 15 and 16. It should be noted that for focusing on a different configuration from the configurations discussed above, description of the same configuration as the configurations in FIGS. 13 and 14 is omitted.

FIG. 15 is a plan view illustrating an example structure capable of expanding an open area and improving transmittance in the optical area OA of the display panel 110 according to aspects of the present disclosure.

Referring to FIG. 15, in one or more embodiments, in the display panel 110 according to aspects of the present disclosure, the optical area OA may include a plurality of transmissive areas TA and a low-transmissive area LTA different from the plurality of transmissive areas TA.

Each of the plurality of transmissive areas TA may represent a respective cathode hole CH. A light emitting area EA may not be disposed in the plurality of transmissive areas TA.

Referring to FIG. 15, the low-transmissive area LTA may include a plurality of light emitting areas EA. Accordingly, a plurality of light emitting elements ED forming a plurality of light emitting areas EA may be disposed in the low-transmissive area LTA.

As described above, the low-transmissive area LTA may be an area through which light cannot be transmitted or an area through which light can be transmitted at lower transmittance than the plurality of transmissive areas TA.

The optical area OA of FIG. 15 may be implemented in the first type (i.e., the anode extension type) or the second type (i.e., the hole type).

In the example where the optical area OA of FIG. 15 is implemented in the first type, pixel circuits SPC for driving light emitting elements ED may not be disposed in the low-transmissive area LTA in the optical area OA, but may be disposed in an optical bezel area OBA surrounding the optical area OA.

In the example where the optical area OA of FIG. 15 is implemented in the second type, pixel circuits SPC for driving light emitting elements ED may be disposed in the low-transmissive area LTA in the optical area OA.

Referring to FIG. 15, a first light emitting area EA1, a second light emitting area EA2, a third light emitting area EA3, and a transmissive area TA may be disposed along line B-B′. For example, the first light emitting area EA1 may be a red light emitting area EA_R, the second light emitting area EA2 may be a green light emitting area EA_G, and the third light emitting area EA3 may be a blue light emitting area EA_B.

Referring to FIG. 15, in one or more embodiments, the display panel 110 of the display device 100 according to aspects of the present disclosure may have, as an open area expansion and transmittance improvement structure, a structure in which a black matrix BM is not disposed in boundary areas of light emitting areas EA in the optical area OA (compared with the configuration of FIG. 13).

Further, referring to FIG. 15, in one or more embodiments, the display panel 110 of the display device 100 according to the exemplary embodiments of the present disclosure may have, as an open area expansion and transmittance improvement structure, a structure in which a light shield LS is disposed under a respective light emitting element ED in each of the light emitting areas EA in the optical area OA.

Hereinafter, a vertical structure (e.g., a stackup configuration) taken along line B-B′ of FIG. 15 will be described through a cross-sectional view of FIG. 16.

FIG. 16 is an example cross-sectional view taken along line B-B′ of FIG. 15 according to one embodiment. It should be noted that for focusing on a different configuration from the configurations discussed above, description of the same configuration as the configurations in FIG. 14 is omitted.

Referring to FIG. 16, in one or more embodiments, the display panel 110 of the display device 100 according to aspects of the present disclosure may include: a substrate SUB including a display area DA that allows an image to be displayed, and includes an optical area OA allowing light to be transmitted and a normal area NA located outside of the optical area OA; a first light emitting element ED1 disposed in the optical area OA; a second light emitting element ED2 disposed in the optical area OA and spaced apart from the first light emitting element ED1; a first color filter CF1 disposed in the low-transmissive area LTA of the optical area OA and located on the first light emitting element ED1; and a second color filter CF2 disposed in the low-transmissive area LTA of the optical area OA, located on the second light emitting element ED2, and spaced apart from the first color filter CF1.

Referring to FIG. 16, in one or more embodiments, the display panel 110 of the display device 100 according to aspects of the present disclosure may further include a first light shield LS1 disposed in the low-transmissive area LTA of the optical area OA and located under the first light emitting element ED1 so as to overlap the first light emitting element ED1, and a second light shield LS2 disposed in the low-transmissive area LTA of the optical area OA and located under the second light emitting element ED2 so as to overlap the second light emitting element ED2. As shown in FIG. 16, the first light shield LS1 overlaps the first light emitting element ED1 such that the first light emitting element ED1 is between the first light shield LS1 and the first color filter CF1. Similarly, the second light shield LS2 overlaps the second light emitting element ED2 such that the second light emitting element ED2 is between the second light shield LS1 and the second color filter CF2.

Referring to FIG. 16, in one or more embodiments, in the display panel 110 of the display device 100 according to aspects of the present disclosure, a black matrix BM may not be disposed between the first color filter CF1 and the second color filter CF2.

Referring to FIG. 16, since a black matrix BM is not present between the first color filter CF1 and the second color filter CF2, first light L1, which is external light, can be incident between the first color filter CF1 and the second color filter CF2, but can be shielded by the first light shield LS1. Accordingly, one or more optical electronic devices (11 and/or 12) located under the substrate SUB can be prevented from malfunctioning due to the first light L1, which is external light.

Referring to FIG. 16, second light L2, which is external light incident through the second color filter CF2, can be shielded by the second anode electrode AE2. Accordingly, the one or more optical electronic devices (11 and/or 12) located under the substrate SUB can be prevented from malfunctioning due to the second light L2, which is external light.

Referring to FIG. 16, in a transmissive area TA of the optical area OA, third light L3 incident to the front surface can be transmitted, and exit from the rear surface of the substrate SUB. The third light L3 may be light needed for the operation of the one or more optical electronic devices (11 and/or 12).

Referring to FIG. 16, in one or more embodiments, the display panel 110 of the display device 100 according to aspects of the present disclosure may further include a third light emitting element ED3 disposed in the low-transmissive area LTA of the optical area OA and spaced apart from the first light emitting element ED1 and the second light emitting element ED2, a third color filter CF3 disposed in the optical area OA and located on the third light emitting element ED3, and a third light shield LS3 disposed in the optical area OA and located under the third light emitting element ED3 so as to overlap the third light emitting element ED3.

Referring to FIG. 16, in one or more embodiments, in the display panel 110 of the display device 100 according to aspects of the present disclosure, a black matrix BM may not be disposed between the first color filter CF1 and the second color filter CF2, between the second color filter CF2 and the third color filter CF3, and between the first color filter CF1 and the third color filter CF3.

Referring to FIG. 16, all or at least a portion of the first light shield LS1 may overlap the first color filter CF1.

Referring to FIG. 16, in an example where a width of the first light shield LS1 is greater than a width of the first color filter CF1, both ends or edges of the first light shield LS1 are non-overlapping with the first color filter CF1.

Referring to FIG. 16, a distance D2 from one end of the first light shield LS1 to one end of the first color filter CF1 may correspond to a length of a portion of the first light shield LS1 that is non-overlapping with the first color filter CF1. That is, the distance D2 corresponds to a length of an end of the first light shield LS1 that extends past the end of the first color filter CF1.

Referring to FIG. 16, the first light shield LS1 and the second light shield LS2 may be spaced apart from each other. Due to this implementation, in the low-transmissive area LTA of the optical area OA, fourth light L4 incident between the first color filter CF1 and the second color filter CF2 can be transmitted through an area between the first light shield LS1 and the second light shield LS2, and exit from the rear surface of the substrate SUB. The fourth light L4 may be light needed for the operation of the one or more optical electronic devices (11 and/or 12).

As described above, since the first light shield LS1 and the second light shield LS2 are spaced apart from each other, transmittance of the low-transmissive area LTA of the optical area OA can be improved.

Referring to FIG. 16, the second light shield LS2 and the third light shield LS3 may be spaced apart from each other. Due to this implementation, in the low-transmissive area LTA of the optical area OA, fifth light L5 incident between the second color filter CF2 and the third color filter CF3 can be transmitted through an area between the second light shield LS2 and the third light shield LS3, and exit from the rear surface of the substrate SUB. The fifth light L5 may be light needed for the operation of the one or more optical electronic devices (11 and/or 12).

As described above, since the first light shield LS1 and the second light shield LS2 are spaced apart from each other, transmittance of the low-transmissive area LTA of the optical area OA can be improved.

Referring to FIG. 16, for example, a separation distance D1s between the first light shield LS1 and the second light shield LS2 may be less than or equal to a separation distance Dcf between the first color filter CF1 and the second color filter CF2.

Referring to FIG. 16, the first light emitting element ED1 may include a first anode electrode AE1, a first emission layer EL1, and a cathode electrode CE. A bank BK may be located on the first anode electrode AE), and include an opening for exposing a portion of the first anode electrode AE1.

Referring to FIG. 16, the first color filter CF1 may overlap the opening of the bank BK and may also overlap one or more portions of the bank BK around the opening of the bank BK.

A length D1 between one end of the first color filter CF1 and the opening of the bank BK may be a length of an overlap area between the first color filter CF1 and the bank BK.

For example, as shown in FIG. 16, each of the first light shield LS1, the second light shield LS2, and the third light shield LS3 may be formed independently of one another. In another example, all or at least a portion of the first light shield LS1, the second light shield LS2, and the third light shield LS3 may be integrally formed.

Referring to FIG. 16, in one or more embodiments, the display panel 110 according to aspects of the present disclosure may include an encapsulation layer ENCAP on the first and second light emitting elements (ED1 and ED2), and a touch sensor layer TSL on the encapsulation layer ENCAP.

The touch sensor layer TSL may include one or more touch sensor metals TSM and may further include one or more bridge metals BRG.

Referring to FIG. 16, in one or more embodiments, in the optical area OA included in the display area DA of the display panel 110 according to aspects of the present disclosure, the one or more touch sensor metals TSM may not overlap the first color filter CF1 and the second color filter CF2.

Referring to FIG. 16, for example, the first color filter CF1 and the second color filter CF2 may be located on the touch sensor layer TSL. Any one of the one or more touch sensor metals TSM may be located between the first color filter CF1 and the second color filter CF2. Accordingly, display quality may not be affected by the one or more touch sensor metals TSM.

Referring to FIG. 16, for example, the one or more touch sensor metals TSM may not overlap the first light shield LS1 and the second light shield LS2. That is, any one of the one or more touch sensor metals TSM may be disposed in a space between the first light shield LS1 and the second light shield LS2.

Referring to FIG. 16, the touch sensor layer TSL may include a sensor buffer layer S-BUF on the encapsulation layer ENCAP, the one or more bridge metals BRG on the sensor buffer layer S-BUF, a sensor interlayer insulating layer S-ILD disposed on the one or more bridge metals BRG such that the sensor interlayer insulating film S-ILD covers on the one or more bridge metals BRG, and the one or more touch sensor metals TSM on the sensor interlayer insulating layer S-ILD.

The sensor interlayer insulating layer S-ILD may include a touch interlayer insulating layer T-ILD and an organic interlayer insulating layer O-ILD. For example, the touch interlayer insulating layer T-ILD may be an inorganic layer, and the organic interlayer insulating layer O-ILD may be an organic layer.

Referring to FIG. 16, the display panel 110 may further include a color filter buffer layer C-BUF disposed on the one or more touch sensor metals TSM such that the color filter buffer layer C-BUF covers the one or more touch sensor metals TSM, and an overcoat layer OC disposed on the first and second color filters (CF1 and CF2) such that the overcoat layer OC covers the first and second color filters (CF1 and CF2).

The first color filter CF1 and the second color filter CF2 may be located on the color filter buffer layer C-BUF.

Referring to FIG. 16, at least one of the sensor interlayer insulating layer S-ILD and the encapsulation layer ENCAP may include an organic layer or an organic material. For example, the organic interlayer insulating layer O-ILD may include an organic layer, and the second encapsulation layer PCL may include an organic layer.

The optical area OA in FIGS. 15 and 16 may include a plurality of transmissive areas TA and a low-transmissive area LTA different from the plurality of transmissive areas TA.

The first light emitting element ED1 and the second light emitting element ED2 may be disposed in the low-transmissive area LTA. The low transmission area LTA may not allow light to be transmitted or may allow light to be transmitted at lower transmittance than the plurality of transmissive areas TA.

In the example where the optical area OA in FIGS. 15 and 16 is implemented in the first type (i.e., the anode extension type), a first pixel circuit SPC for driving the first light emitting element ED1 may not be disposed in the low-transmissive area LTA of the optical area OA, but may be disposed in an optical bezel area OBA surrounding the optical area OA. For example, the optical bezel area OBA may be an area outside of the optical area OA.

A first anode extension line AEL may interconnect the first light emitting element ED1 disposed in the optical area OA and the first pixel circuit disposed in the optical bezel area OBA. The first anode extension line AEL may include a transparent material. Accordingly, transmittance of the optical area OA can be improved.

In the example where the optical area OA in FIGS. 15 and 16 is implemented in the second type (i.e., the hole type), the first pixel circuit SPC for driving the first light emitting element ED1 may be disposed in the low-transmissive area LTA of the optical area OA.

As described above, in one or more embodiments, the display device 100 according to aspects of the present disclosure may include one or more optical electronic devices (11 and/or 12) located under the substrate SUB and overlapping the optical area OA.

For example, the optical area OA may include a first optical area OA1 and a second optical area OA2.

In this example, the display device 100 according to aspects of the present disclosure may include the first optical electronic device 11 located under the substrate SUB and overlapping the first optical area OA1, and the second optical electronic device 12 located under the substrate SUB and overlapping the second optical area OA2.

The first optical electronic device 11 can perform a predefined operation by using first light transmitting through the first optical area OA1 and having a first range of wavelengths. The second optical electronic device 12 can perform a predefined operation by using second light transmitting through the second optical area OA2 and having a second range of wavelengths.

For example, in examples where the first optical electronic device 11 is a camera, and the second optical electronic device 12 is an infrared sensor, the first range of wavelengths may be visible light wavelengths, and the second range of wavelengths may be infrared light wavelengths.

As described above, since the optical area OA has a structure in which a black matrix BM is not disposed and one or more light shields LS are disposed under one or more light emitting elements ED, external light passing through one or more color filter layer CFL (L1 and/or L2) can be shielded, and each open area or a total of open areas can be expanded. Accordingly, transmittance can be maximized.

As described above, since the optical area OA has a structure in which a black matrix BM is not disposed and one or more light shields LS are disposed under one or more light emitting elements ED, external light passing through one or more color filter layer CFL (L1 and/or L2) can be shielded, and thereby, the one or more optical electronic devices (11 and/or 12) such as a camera, an infrared sensor, and the like can be prevented from malfunctioning.

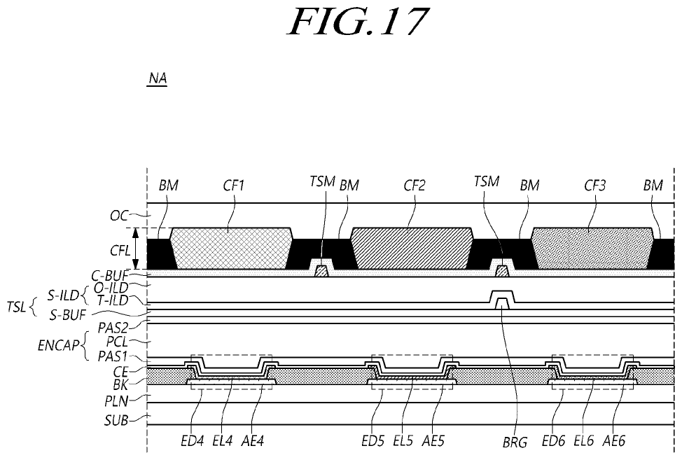

Hereinafter, in the display device 100 according to aspects of the present disclosure, in the examples where the optical area OA has the open area expansion and transmittance improvement structure as discussed above with reference to FIGS. 15 and 16, a structure in the normal area NA will be discussed with reference to FIG. 17.

FIG. 17 is an example cross-sectional view of the normal area NA in the display panel 110 according to embodiments of the present disclosure.

Referring to FIG. 17, in the display panel 110 according to aspects of the present disclosure, the normal area NA may not have an open area expansion and transmittance improvement structure as in the optical area OA.

Referring to FIG. 17, the display panel 110 according to aspects of the present disclosure may include a fourth light emitting element ED4 disposed in the normal area NA, a fifth light emitting element ED5 disposed in the normal area NA and spaced apart from the fourth light emitting element ED4, a fourth color filter CF4 disposed in the normal area NA and located on the fourth light emitting element ED4, and a fifth color filter CF5 disposed in the normal area NA, located on the fifth light emitting element ED5, and spaced apart from the fourth color filter CF4.

Referring to FIG. 17, a black matrix BM may be disposed between the fourth color filter CF4 and the fifth color filter CF5.

Referring to FIG. 17, the display panel 110 according to aspects of the present disclosure may include a sixth light emitting element ED6 disposed in the normal area NA, and a sixth color filter CF6 disposed in the normal area NA and located on the sixth light emitting element ED6.

Referring to FIG. 17, a black matrix BM may be disposed between the sixth color filter CF6 and the fifth color filter CF5.

Referring to FIG. 17, in the display panel 110 according to aspects of the present disclosure, a light shield LS may not be disposed under each of the fourth to sixth light emitting elements (ED4, ED5, and ED6).

In the embodiments described above, the structure of the optical area OA and the structure of the normal area NA can be compared as follows.

Referring to FIGS. 16 and 17, the display device 100 according to aspects of the present disclosure may include: the first light emitting element ED1 disposed in a first area (the optical area OA) included in the display area DA in which one or more images can be displayed; the first color filter CF1 disposed in the first area and located on the first light emitting element ED1; the fourth light emitting element ED4 included in the display area DA and disposed in a second area (the normal area NA) different from the first area (the optical area OA); the fourth color filter CF4 disposed in the second area and located on the fourth light emitting element ED4; a light shield LS located only under the first light emitting element ED1 among the first light emitting element ED1 and the fourth light emitting element ED4; a black matrix BM disposed only on at least one side of the fourth color filter CF4 among the first color filter CF1 and the fourth color filter CF4.

The embodiments of the display panel 110 and the touch display device 100 according to aspects of the present disclosure described above can be briefly discussed as follows.

According to aspects of the present disclosure, the display device 100 can be provided that includes: a substrate including a display area that allows one or more images to be displayed, and includes an optical area allowing light to be transmitted and a normal area located outside of the optical area; a first light emitting element disposed in the optical area; a first color filter disposed in the optical area and located on the light emitting element; and a first light shield disposed in the optical area and located under the first light emitting element.

In the optical area of the display device, a black matrix may not be disposed between the first color filter and a second color filter.

In the optical area of the display device, all or at least a portion of the first light shield may overlap the first color filter.

In the optical area of the display device, at least a portion of both edges of the first light shield may not overlap the first color filter.

In the optical area of the display device, the first light emitting element may include a first anode electrode, a first emission layer, and a cathode electrode.

The display device may further include a bank located on the first anode electrode and having an opening for exposing a portion of the first anode electrode.

In the optical area of the display device, the first color filter may overlap the opening, and may also overlap at least a portion of the bank around the opening.

The display device may further include a second light emitting element disposed in the optical area and spaced apart from the first light emitting element, a second color filter disposed in the optical area, located on the second light emitting element, and spaced apart from the first color filter, and a second light shield disposed in the optical area and located under the second light emitting element.

In this implementation, the first light shield and the second light shield may be disposed to be spaced apart from each other. A separation distance between the first light shield and the second light shield may be less than or equal to a separation distance between the first color filter and the second color filter.

The display device may further include an encapsulation layer on the first light emitting element and the second light emitting element, and a touch sensor layer on the encapsulation layer.

The touch sensor layer may include one or more touch sensor metals.

The one or more touch sensor metals may not overlap the first color filter and the second color filter. That is, the touch sensor metals may be disposed in a space between the first color filter and the second color filter.

The first color filter and the second color filter may be located on the encapsulation layer.

For example, the first color filter and the second color filter may be located on the touch sensor layer.

The touch sensor metal may be located between the first color filter and the second color filter.

The one or more touch sensor metals may not overlap the first light shield and the second light shield. For example, the touch sensor metal may be disposed in a space between the first light shield and the second light shield.

In the display device, the touch sensor layer may include a sensor buffer layer on the encapsulation layer, one or more bridge metals on the sensor buffer layer, a sensor interlayer insulating layer disposed on the one or more bridge metals such that the sensor interlayer insulating layer covers the one or more bridge metals, and the one or more touch sensor metals on the sensor interlayer insulating layer.

At least one of the sensor interlayer insulating layer and the encapsulation layer may include an organic layer or an organic material.

In the display device, the optical area may include a plurality of transmissive areas and a low-transmissive area different from the plurality of transmissive areas.

The first light emitting element may be disposed in the low-transmissive area.

The low-transmissive area may be an area not allowing light to be transmitted, or a transmissive area allowing light to be transmitted at lower transmittance than the plurality of transmissive areas.

The display device may further include a first pixel circuit for driving the first light emitting element.

When the optical area is implemented in the first type (i.e., the anode extension type), the display area may further include an optical bezel area surrounding the optical area, and the first pixel circuit may not be disposed in the low-transmissive area of the optical area, and may be disposed in the optical bezel area outside of the optical area.

When the optical area is implemented in the first type (i.e., the anode extension type), the display panel may further include a first anode extension line interconnecting the first light emitting element disposed in the optical area and the first pixel circuit disposed in the optical bezel area.

The first anode extension line may include a transparent material.

When the optical area is implemented in the second type (i.e., the hole type), the first pixel circuit may be disposed in the low-transmissive area of the optical area.

The display device may further include one or more optical electronic devices disposed under the substrate and overlapping the optical area.

In the display device, the optical area may include a first optical area and a second optical area.

The display device may further include a first optical electronic device located under the substrate and overlapping the first optical area, and a second optical electronic device located under the substrate and overlapping the second optical area.

The first optical electronic device can perform a predefined operation using first light transmitting through the first optical area and having a first range of wavelengths. The second optical electronic device can perform a predefined operation by using second light transmitting through the second optical area and having a second range of wavelengths.

The display device may further include a fourth light emitting element disposed in the normal area, a fifth light emitting element disposed in the normal area and spaced apart from the fourth light emitting element, a fourth color filter disposed in the normal area and disposed on the fourth light emitting element, and a fifth color filter disposed in the normal area, located on the fifth light emitting element, and spaced apart from the fourth color filter.

In the normal area, a black matrix may be disposed between the fourth color filter and the fifth color filter.

According to aspects of the present disclosure, the display panel 110 can be provided that includes: a first light emitting element disposed in a first area included in a display area in which one or more images can be displayed; a first color filter disposed in the first area and located on the first light emitting element; a second light emitting element included in the display area and disposed in a second area different from the first area; a second color filter disposed in the second area and located on the second light emitting element; a light shield located only under the first light emitting element among the first light emitting element and the second light emitting element; and a black matrix disposed only on at least one side of the second color filter among the first color filter and the second color filter.

According to the embodiments described herein, the display panel 110 and the display device 100 may be provided that include a light transmission structure for enabling one or more optical electronic devices to normally receive light (e.g., visible light, infrared light, ultraviolet light, or the like) while not being exposed in a front surface of the display device.

According to the embodiments described herein, the display panel 110 and the display device 100 may be provided that have a structure for enabling expansion of an open area in an optical area of the display panel overlapping one or more optical electronic devices.

According to the embodiments described herein, the display panel 110 and the display device 100 may be provided that have a structure capable of improving luminance efficiency in an optical area included in a display area of the display panel, and thereby, enabling low-power designs.

According to the embodiments described herein, the display panel 110 and the display device 100 may be provided that have a structure capable of increasing of transmittance (or transmissivity) of an optical area of the display panel overlapping one or more optical electronic devices.

According to the embodiments described herein, an advantage of improving operating performance of one or more optical electronic devices located under the display panel can be provided.

According to the embodiments described herein, the display panel 110 and the display device 100 may be provided that have a structure capable of preventing one or more optical electronic devices overlapping an optical area of the display panel from malfunctioning by external light.

Additional features and aspects will be set forth in part in the description which follows and in part will become apparent from the description or may be learned by practice of the inventive concepts provided herein. Other features and aspects of the inventive concepts may be realized and attained by the structure particularly pointed out in, or derivable from, the written description, the claims hereof, and the appended drawings.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims.

It is to be understood that both the foregoing general description and the following detailed description of the present disclosure are exemplary and explanatory and are intended to provide further explanation of the inventive concepts as claimed.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a substrate comprising a display area including an optical area configured to display an image and allow light to be transmitted through the optical area and a normal area located outside of the optical area and configured to display the image;
a first light emitting element in the optical area;
a first color filter in the optical area and overlapping the first light emitting element; and
a first light shield in the optical area and overlapping the first light emitting element.

2. The display device of claim 1, wherein the optical area lacks a black matrix between the first color filter and a second color filter that is adjacent to the first color filter in the optical area.

3. The display device of claim 1, wherein all or at least a portion of the first light shield overlaps the first color filter, and
wherein at least a portion of both edges of the first light shield are non-overlapping with the first color filter.

4. The display device of claim 1, wherein the first light emitting element comprises a first anode electrode, a first emission layer on the first anode electrode, and a cathode electrode on the first emission layer, and the display device further comprises:
a bank on the first anode electrode, the bank having an opening that exposes a portion of the first anode electrode,
wherein the first color filter overlaps the opening and at least a portion of the bank around the opening.

5. The display device of claim 1, further comprising:
a second light emitting element in the optical area, the second light emitting element spaced apart from the first light emitting element;
a second color filter in the optical area and overlapping the second light emitting element, the second color filter spaced apart from the first color filter; and
a second light shield in the optical area and overlapping the second light emitting element,
wherein the first light shield and the second light shield are spaced apart from each other such that a separation distance between the first light shield and the second light shield is less than or equal to a separation distance between the first color filter and the second color filter.

6. The display device of claim 5, further comprising:
an encapsulation layer on the first light emitting element and the second light emitting element; and
a touch sensor layer on the encapsulation layer, the touch sensor layer comprising one or more touch sensor metals that are non-overlapping with the first color filter and the second color filter.
wherein the first color filter and the second color filter are on the encapsulation layer.

7. The display device of claim 6, wherein the first color filter and the second color filter are on the touch sensor layer, and one of the one or more touch sensor metals is between the first color filter and the second color filter, and
wherein the one or more touch sensor metals are non-overlapping with the first light shield and the second light shield.

8. The display device of claim 6, wherein the touch sensor layer comprises:
a sensor buffer layer on the encapsulation layer;
one or more bridge metals on the sensor buffer layer; and
a sensor interlayer insulating layer covering the one or more bridge metals,
wherein the one or more touch sensor metals are on the sensor interlayer insulating layer, and
wherein at least one of the sensor interlayer insulating layer or the encapsulation layer comprises an organic layer or an organic material.

9. The display device of claim 1, wherein the optical area comprises a plurality of transmissive areas and a low-transmissive area that is different from the plurality of transmissive areas, the low-transmissive area configured to not allow light to be transmitted through the low-transmissive area or allow less light to be transmitted through the low-transmissive area than the plurality of transmissive areas,
wherein the first light emitting element is in the low-transmissive area.

10. The display device of claim 9, wherein the optical area further comprises an optical bezel area surrounding the optical area, the display device further comprising:
a first pixel circuit configured to drive the first light emitting element that is in the low-transmissive area of the optical area, the first pixel circuit in the optical bezel area outside of the optical area; and
a first anode extension line interconnecting the first light emitting element that is in the low-transmissive area of the optical area and the first pixel circuit that is in the optical bezel area, the first anode extension line comprising a transparent material.

11. The display device of claim 9, further comprising:
a first pixel circuit configured to drive the first light emitting element, the first pixel circuit in the low-transmissive area of the optical area.

12. The display device of claim 1, wherein the optical area comprises a first optical area and a second optical area, and the display device further comprises:
a first optical electronic device under the substrate and overlapping the first optical area; and
a second optical electronic device under the substrate and overlapping the second optical area,
wherein the first optical electronic device is configured to perform a predefined operation using first light transmitting through the first optical area and the first light having a first range of wavelengths, and the second optical electronic device is configured to perform a predefined operation using second light transmitting through the second optical area and the second light having a second range of wavelengths.

13. The display device of claim 1, further comprising:
a fourth light emitting element in the normal area;
a fifth light emitting element in the normal area and spaced apart from the fourth light emitting element;
a fourth color filter in the normal area and overlapping the fourth light emitting element;
a fifth color filter in the normal area and spaced apart from the fourth color filter, the fifth color filter overlapping the fifth light emitting element; and
a black matrix between the fourth color filter and the fifth color filter.

14. A display device comprising:
a first light emitting element in a first area of a display area of a display panel in which an image is displayed;
a first color filter in the first area and overlapping the first light emitting element;
a second light emitting element in a second area of the display area that is different from the first area;
a second color filter in the second area and overlapping the second light emitting element;
a light shield located under the first light emitting element but is non-overlapping with the second light emitting element; and
a black matrix on at least one side of the second color filter in the second area without being on the first color filter in the first area.

15. The display device of claim 14, wherein the first area is configured to display the image and allow light transmission through the first area, and the second area is configured to display the image without allowing light transmission through the second area.

16. A display device comprising:
a substrate including a first area configured to display an image and allow external light to be transmitted through the first area, and a second area located outside of the first area and configured to display the image without allowing the external light to be transmitted through the second area;
a first light emitting element in the first area, the first light emitting element configured to emit light;
a first pixel circuit connected to the first light emitting element, the first pixel circuit in one of the first area or the second area;
a first color filter in the first area, the first color filter overlapping the first light emitting element; and
a first light shield in the first area, the first light shield overlapping the first color filter and the first light emitting element such that an end of the first light shield extends past an end of the first color filter.

17. The display device of claim 16, further comprising:
a second light emitting element in the first area, the second light emitting element configured to emit light;
a second pixel circuit connected to the second light emitting element, the second pixel circuit in one of the first area or the second area;
a second color filter in the first area, the second color filter overlapping the second light emitting element; and
a second light shield in the first area, the second light shield overlapping the second color filter and the second light emitting element such that an end of the second light shield extends past an end of the second color filter.

18. The display device of claim 17, wherein a distance between the first light shield and the second light shield is less than a distance between the first color filter and the second color filter.

19. The display device of claim 17, further comprising:
a black matrix between color filters in the second area without being between the first color filter and the second color filter in the first area.

20. The display device of claim 16, wherein the first pixel circuit is in the second area and the display device further comprises:
an extension line that extends from the second area to the first area and connects the first pixel circuit in the second area to an anode electrode of the first light emitting element in the second area.
